(19) United States
(12) Patent Application Publication
(10) Pub. No.: US 2026/0247966 A1
(43) Pub. Date: Aug. 20, 2026

(54) BACKSIDE POWER DELIVERY

(71) Applicant: Adeia Semiconductor Bonding Technologies Inc., San Jose, CA (US)

(72) Inventors: Belgacem Haba, Saratoga, CA (US); Rasit Onur Topaloglu, Poughkeepsie, NY (US)

(21) Appl. No.: 19/058,954

(22) Filed: Feb. 20, 2025

(51) Int. Cl. H01L 23/46; H01L 23/00

(52) U.S. Cl. CPC H10W 40/40; H10W 90/792

(57) ABSTRACT

Embodiments herein provide for stacked semiconductor devices and related manufacturing methods. A stacked semiconductor device comprises a first semiconductor device and a second semiconductor device. The second semiconductor device comprises one or more circuits to deliver power to one or more components in a front portion of the first semiconductor device.

The second semiconductor device or an apparatus including the second semiconductor device is directly bonded to a backside of the first semiconductor device.

### FIELD

The present disclosure relates to power delivery for devices, and in particular, active power delivery for semiconductor devices and methods of manufacturing the same.

### BACKGROUND

Power may be drawn (e.g., pulled, used, taken or consumed from a source) from the front or frontside of chips (e.g., devices, semiconductor devices, wafers, substrates). As number of connections (e.g., input/outputs, pins) on a package increases, it becomes challenging to fit all connections on a frontside of a chip. Accordingly, there exists a need in the art for improved power delivery for a chip (e.g., device, semiconductor device, wafer, substrate) and methods of manufacturing the same.

### SUMMARY

Embodiments herein provide for power delivery from a back or backside of a semiconductor device using an active power delivery chip (e.g., a separate substrate including one or more active power delivery components attached to a backside of a semiconductor device or a chip or substrate without the one or more active power delivery components, without any active power delivery components, without some active power delivery components, or having fewer active power delivery components compared to a chip including the one or more active power delivery components). Advantageously, a size of the semiconductor device may decrease (e.g., by reducing a number I/O (input/output) pads) and/or a number of I/Os can be increased.

A first general aspect includes a stacked semiconductor device comprising a first semiconductor device and a second semiconductor device. The second semiconductor device comprises one or more circuits to deliver power. The second semiconductor device is directly bonded to a backside of the first semiconductor device. In some embodiments, the first semiconductor device has a backside, the second semiconductor device has a frontside, and the backside of the first semiconductor device and the frontside of the second semiconductor device are directly bonded. In some embodiments, the second semiconductor device comprises one or more power regulators, and the one or more power regulators are in a front portion of the second semiconductor device and drive one or more components in a front portion of the first semiconductor device. In some embodiments, the first semiconductor device comprises one or more first power regulators in a front portion of the first semiconductor device, the second semiconductor device comprises one or more second power regulators in a front portion of the second semiconductor device, and the one or more first power regulators and the one or more second power regulators drive one or more components in the front portion of the first semiconductor device.

In some embodiments, the first semiconductor device is a chip, and the second semiconductor device is an active power delivery chip. The active power delivery chip may comprise at least one of: a power switch, a low-dropout regulator, a buck converter, a charge pump, a boost converter, a battery management circuit, a voltage monitor circuit, a current sensor, a dynamic voltage and frequency scaling circuit, or a battery protection circuit.

In some embodiments, the backside of the first semiconductor device is hybrid bonded to the frontside of the second semiconductor device. In some embodiments, the second semiconductor device drives the first semiconductor device.

In some embodiments, a cold plate is attached to a backside of the second semiconductor device. The cold plate may comprise a semiconductor material, a plurality of coolant channels, and at least one via. The at least one via may be disposed between two coolant channels. The plurality of coolant channels may face the second semiconductor device. The plurality of coolant channels may face away from the second semiconductor device. At least one first coolant channel of the plurality of coolant channels may face the second semiconductor device, and at least one second coolant channel of the plurality of coolant channels may face away from the second semiconductor device.

In some embodiments, the second semiconductor device further comprises a semiconductor material, a plurality of coolant channels facing away from the first semiconductor device, and at least one via. The at least one via may be disposed between two coolant channels.

A second general aspect includes a stacked semiconductor device comprising a first semiconductor device attached to an apparatus comprising a plurality of second semiconductor devices. At least one of the second semiconductor devices of the plurality of the second semiconductor devices comprises one or more circuits to deliver power. The at least one of the second semiconductor devices of the plurality of the second semiconductor devices may drive the first semiconductor device. The apparatus is directly bonded to a backside of the first semiconductor device, and an edge of each second semiconductor device faces a backside of the first semiconductor device. In some embodiments, the first semiconductor device comprises one or more first power regulators in a front portion of the first semiconductor device. At least one of the second semiconductor devices of the plurality of the second semiconductor devices may comprise one or more second power regulators. The one or more first power regulators and the one or more second power regulators may drive one or more components in the front portion of the first semiconductor device.

In some embodiments, the apparatus further comprises at least one spacer between two second semiconductor devices. An edge of the at least one spacer may define a coolant channel facing towards the first semiconductor device, along with a portion of a top surface of the first semiconductor device and portions of the two second semiconductor devices. An edge of the at least one spacer may define a coolant channel facing away from the first semiconductor device, along with a portion of a cover plate and portions of the two second semiconductor devices.

In some embodiments, at least one second semiconductor device is between two spacers. An edge of the at least one second semiconductor device may define a coolant channel facing towards the first semiconductor device, along with a portion of a top surface of the first semiconductor device and portions of the two spacers.

In some embodiments, each second semiconductor device may be embedded in a corresponding spacer. A coolant channel facing the second semiconductor device may be disposed in at least one spacer. A coolant channel facing away from the second semiconductor device may be disposed in at least one spacer. A first coolant channel facing the second semiconductor device may be disposed in a first spacer, and a second coolant channel facing away from the second semiconductor device may be disposed in a second spacer.

In some embodiments, the first semiconductor device is directly hybrid bonded to the apparatus.

A third general aspect includes a method of manufacturing a stacked semiconductor device according to the first general aspect. The method includes providing a first semiconductor device, providing a second semiconductor device comprising one or more circuits to deliver power, and attaching the second semiconductor device to the backside of the first semiconductor device. The attaching the second semiconductor device to the backside of the first semiconductor device may comprise directly bonding or directly hybrid bonding the second semiconductor device to the backside of the first semiconductor device.

A fourth general aspect includes a method of manufacturing a stacked semiconductor device according to the second general aspect. The method includes providing a first semiconductor device, providing an apparatus comprising a plurality of second semiconductor devices, and attaching an edge of the apparatus to the backside of the first semiconductor device. The attaching the edge of the apparatus to the backside of the first semiconductor device may comprise directly bonding or directly hybrid bonding the edge of the apparatus to the backside of the first semiconductor device.

A fifth general aspect includes a method of manufacturing an integrated cooling assembly according to the first aspect or the second aspect. The method includes providing a first substrate comprising a cold plate, providing a second substrate comprising a semiconductor device, and attaching the first substrate to the second substrate. In some embodiments, the method may include providing the second substrate comprising a stacked semiconductor device (e.g., a second semiconductor device comprising one or more circuits to deliver power attached to a backside of a first semiconductor device). In some embodiments, the method may include providing the first substrate comprising the cold plate comprising a second semiconductor device, and providing the second substrate comprising a first semiconductor device. In some embodiments, the method may include providing the first substrate comprising the cold plate comprising an assembly and providing the second substrate comprising the first semiconductor device. In some embodiments, the attaching the first substrate to the second substrate may comprise directly bonding or directly hybrid bonding the first substrate to the second substrate.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 illustrates a device package with an external heat sink;

FIG. 2A is a schematic plan view of an example of a system panel, in accordance with embodiments of the present disclosure;

FIG. 2B is a schematic partial side view of a device package mounted on a PCB, in accordance with embodiments of the present disclosure;

FIG. 2C is a schematic exploded isometric view of the device package in FIG. 2B;

FIG. 3 is a schematic sectional view of an example device package, in accordance with embodiments of the present disclosure, that may be used with the system panel;

FIG. 4 is a schematic sectional view of an integrated cooling assembly of a device package, in accordance with embodiments of the present disclosure;

FIG. 5 is a schematic sectional view of another example device package, in accordance with embodiments of the present disclosure, that may be used with the system panel;

FIG. 6A is a schematic sectional view in the X-Z plane of another integrated cooling assembly, in accordance with embodiments of the present disclosure;

FIG. 6B is a schematic sectional view in the Y-Z plane of the integrated cooling assembly of FIG. 6A, in accordance with embodiments of the present disclosure;

FIG. 7A shows a method that can be used to manufacture the device package described herein;

FIG. 7B shows a method that can be used to manufacture example stacked semiconductor devices described herein;

FIG. 7C shows a method that can be used to manufacture example integrated cooling assemblies described herein;

FIG. 7D shows a method that can be used to manufacture example stacked semiconductor devices described herein;

FIGS. 8A-8C schematically illustrates a stacked semiconductor device, according to some embodiments;

FIG. 9A schematically illustrates bonding semiconductor devices to form an apparatus, according to some embodiments;

FIGS. 9B-9E schematically illustrates an apparatus attached to a semiconductor device, according to some embodiments; and FIGS. 10A-10B schematically illustrate hybrid bonding, according to some embodiments.

The figures herein depict various embodiments of the present disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term “substrate” also includes semiconductor substrates that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As used herein, the term “semiconductor device” may be used interchangeably with “chip,” “device,” “substrate,” and “wafer.” The term “semiconductor device” may refer to a stacked semiconductor device. A stacked semiconductor device may comprise a first semiconductor device (e.g., chip) attached (e.g., directly bonded, hybrid bonded) to a second semiconductor device (e.g., active power delivery chip). A second semiconductor device may comprise one or more circuits to deliver power. A frontside of the second semiconductor device may be attached to a backside of the first semiconductor device. The active power delivery chip may comprise power circuits such as at least one of: a power switch, a low-dropout regulator, a buck converter, a charge pump, a boost converter, a battery management circuit, a voltage monitor circuit, a current sensor, a dynamic voltage and frequency scaling circuit, or a battery protection circuit.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that forms the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axes in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” and the like, either alone or in combination with a spatially relevant term, include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding,” or “directly bonded”). The resultant bonds formed by this technique may be described as “direct bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding (e.g., direct dielectric bonding) provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive or solder. The resultant bonds formed by this technique may be described as “hybrid bonds” and/or “direct hybrid bonds”. In some hybrid bonding embodiments, there are many first conductive features, each directly bonded to a second conductive feature, without any intervening adhesive or solder. In some embodiments, nonconductive features on the first element are directly bonded to nonconductive features of the second element at room temperature without any intervening adhesive, which is followed by direct bonding of conductive features of the first element to conductive features of the second element via annealing at slightly higher temperatures (e.g., >100° C., >200° C., >250° C., >300° C., etc.), wherein the annealing causes the conductive features to expand faster than the non-conductive features and to bond together.

Unless otherwise noted, the terms “cooling assembly” and “integrated cooling assembly” generally refer to a semiconductor device and a cold plate attached to the semiconductor device. For example, the semiconductor device may be a stacked semiconductor device, and the cold plate may be attached to a second semiconductor device that is attached to a first semiconductor device. As another example, the cold plate may comprise a second semiconductor device which is attached to a first semiconductor device. Typically, the cold plate is formed with recessed surfaces that define one or more fluid cavities (e.g., coolant chamber volume(s) or coolant channel(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. While it is preferred that the cold plate is formed of a material whose coefficient of linear thermal expansion (CTE) is the same as or similar to the bulk material of the semiconductor device, in some embodiments the cold plate may comprise one or more materials such as: polymer, copper, aluminum, silicon, glass, or ceramic, for example.

The cold plate may be attached to the semiconductor device by use of an adhesive layer or by direct bonding or hybrid bonding. Direct bonding may include direct dielectric bonding techniques as described herein, and may give rise to direct dielectric bonds. Hybrid bonding may include hybrid bonding techniques as described herein, and may give rise to direct hybrid bonds. For example, the cold plate may include material layers and/or metal features that facilitate direct bonding or hybrid bonding with the semiconductor device. In some embodiments, the backside of the semiconductor device is beneficially directly exposed to coolant fluids flowing through the integrated cooling assembly, thus providing for direct heat transfer therebetween. It will be understood that “coolant fluid” may alternatively be referred to as “cooling fluid”. Unless otherwise noted, the integrated cooling assemblies described herein may be used with any desired fluid, e.g., liquid, gas, and/or vapor-phase coolants, such as water, glycol, etc. In some embodiments, the coolant fluid(s) may contain additives to enhance the conductivity of the coolant fluid(s) within the integrated cooling assemblies. The additives may comprise, for example, nanoparticles of various types, such as carbon nanotubes, graphene, and/or metal oxides. The concentration of these nanoparticles within the coolant fluid may be less than 1%, less than 0.2%, or less than 0.05%. The coolant fluids may also contain a small amount of glycol or glycols (e.g., propylene glycol, ethylene glycol, etc.) to reduce frictional shear stress and drag coefficient in the coolant fluid(s) within the integrated cooling assembly. In some embodiments the coolant fluid may contain entirely glycol or glycols.

Exemplary fluids available for use in the various thermal solution embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Additionally, depending upon design and operating conditions, these fluids may be used in single-phase liquid, single-phase vapor, two-phase liquid/vapor or two-phase solid/liquid. By adjusting the fluid selection and the relative fluid concentrations in the fluid mixtures, it is possible to alter the thermohydraulic and heat transfer properties by altering the temperatures where phase change occurs, enabling meeting design temperature and pressure conditions for the component being cooled or warmed and the thermal solution being deployed. Additionally, different combinations of the fluid phases may be employed in various hybrid configurations to meet the particular cooling or warming needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a thermal solution system using the disclosed embodiments, engineered dielectric coolant fluids may be used. As used herein, a dielectric coolant fluid is a fluid that is thermally conductive but not electrically conductive. Some examples of dielectric fluids used for cooling semiconductors include: 3M™ Fluorinert™ Liquid FC-40—A non-flammable, dielectric fluid that can be used in direct contact with live electronics; 3M™ Novec™ Engineered Fluids—A non-flammable, dielectric fluid that can be used in direct contact with live electronics; Galden® PFPE (perfluoropolyether) products used as heat transfer fluids; EnSolv Fluoro HTF—A solvent with a high boiling point and low pour point that can be used for semiconductor wafer cooling. It is understood that in the selection of the coolant fluid, system design aspects such as operating temperatures and pressures, fluid flow rates, fluid viscosity, and other properties will require evaluation when selecting the appropriate coolant fluid.

In some embodiments, the coolant fluids may contain microparticles and/or nano-particle additives to enhance the conductivity of the coolant fluid within the integrated cooling assemblies. Nanofluids are engineered fluids prepared by suspending the nano-sized (1-100 nm) particles of metals/non-metals and their oxide(s) with a base/conventional fluid. The suspension of high thermal conductivity metals/non-metals and their oxides nano-particles enhances the thermal conductivity and heat transfer ability, etc. of the base fluid. The additives to the underlying coolant fluid may comprise for example, nano-particles of carbon nanotube, nano-particles of graphene, or nano-particles of metal oxides. When the coolant fluid contains microparticles, the microparticles are typically 10 microns or less in diameter. Silicon oxide microparticles may be used.

The volume concentration of these micro or nano-particles within the coolant fluid may be less than 1%, less than 0.2%, or less than 0.05%. Depending upon the liquid and micro/nano-particle type chosen for the coolant fluid, higher volume concentrations of 10% or less, 5% or less, or 2% or less may be used. The coolant fluids may also contain small amounts of glycol or glycols (e.g. propylene glycol, ethylene glycol etc.) to reduce frictional shear stress and drag coefficient in the coolant fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au, etc.), metal oxides (e.g., TiO₂, Al2O₃, CuO, etc.), carbons (e.g. CNTS, graphene, diamond, graphite . . . etc.), or a mixture of different types of nanomaterials. Metal nano-particles (Cu, Ag, Au . . . ) , metal oxide nano-particles (Al₂O₃, TiO₂, CuO), and carbon-based nano-particles are commonly employed elements. Silicon oxide nano-particles may also be used. Using coolant fluids with micro and/or nano-particles when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nano-particles. Magnetic nano-particles may be coated with surfactant layers such as oleic acid to reduce particle agglomeration and/or settling. Magnetic nano-particles used in MNFs are usually made of metal materials (ferromagnetic materials) such as iron, nickel, cobalt, as well as their oxides such as spinel-type ferrites, magnetite (Fe₃O₄), and so forth. The magnetic nano-particles used in MNFs typically range in size from about 1 to 100 nanometers (nm).

This disclosure describes embodiments involving the architecture of system and component elements that can be employed to provide for the cooling of semiconductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

In some embodiments, a cooling channel is a liquid cooling channel, and a liquid may flow through the liquid cooling channel. In some embodiments, the liquid may comprise a water and/or glycol (e.g., propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

Power may be conventionally drawn from the front or frontside of chips (e.g., devices, semiconductor devices, wafers, substrates). As number of connections (e.g., input/outputs, pins) on a package increases, it becomes challenging to fit all connections on a frontside of a chip (e.g., device, semiconductor device, wafer, substrate). Moving at least some of the power of the chip to a backside surface can help enable having more inputs and outputs on the chip. In some embodiments, the active power delivery components of a chip may be removed from the chip to a separate substrate. For example, a second semiconductor device comprising one or more active power delivery components may be attached to a first semiconductor device without the one or more active power delivery components. Advantageously, moving the active power delivery components from a chip can reduce the size of the chip (e.g., remove about 5% to about 10% of the chip real estate or area from reducing a number I/O pads). The active power may be up to or about 10% of the chip power.

Active power delivery components may be power circuits. An active power delivery chip can include power circuits such as power switches, low-dropout regulators, buck converters, charge pumps, boost converters, battery management circuits, voltage monitor circuits, current sensors, dynamic voltage and frequency scaling (DVFS) circuits, and/or battery protection circuits. A power switch may be used in methods for power gating energy minimization or reduction. Low-dropout regulators may be a type of direct current (DC) down-converter that uses capacitors. Buck converters may be a type of DC down-converter that uses switches and inductors. Charge pumps may be a type of DC up-converter that uses capacitors. Boost converters may be a type of DC up-converter that uses switches and inductors. In some embodiments, a plurality of each type of power circuits (e.g., 2, 3 or more, 10, 10 or more, etc.) is distributed along a chip. The power circuits may be close to the chip. In some embodiments, the power circuits may be part of an integrated circuit or IC (e.g., an active power delivery chip or substrate, formed on a same wafer or substrate). In some embodiments, the power circuits may be separately fabricated on different substrates and attached to each other (e.g., hybrid bonded to form a monolithic chip or substrate).

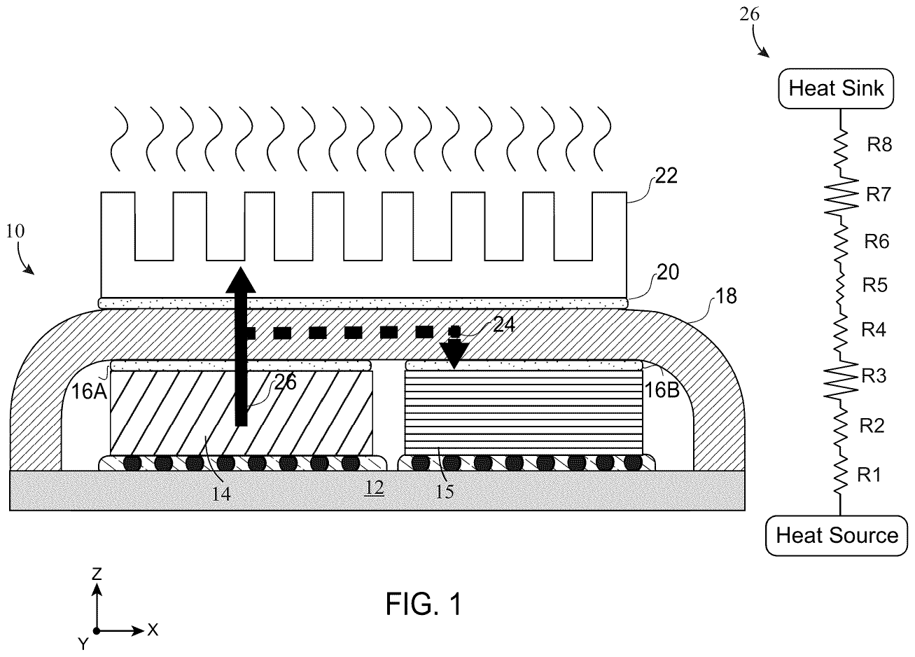

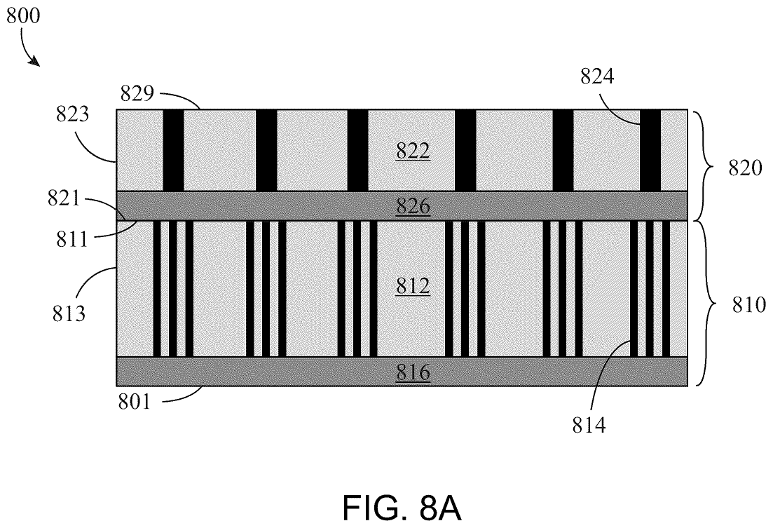

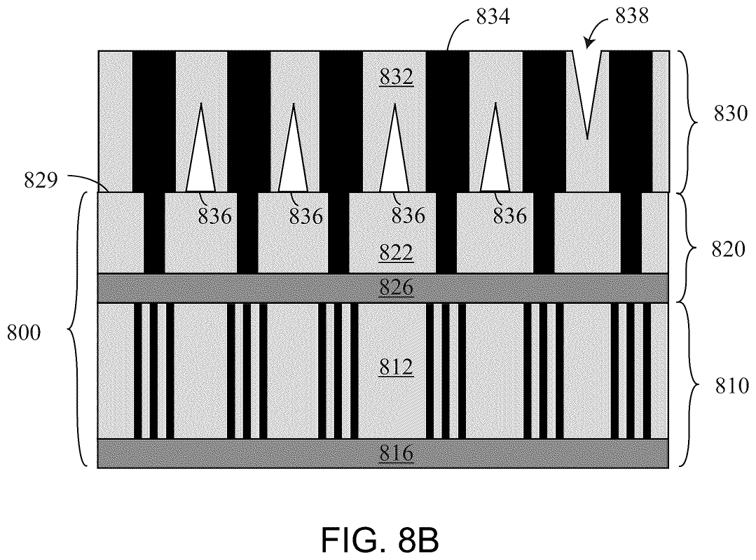

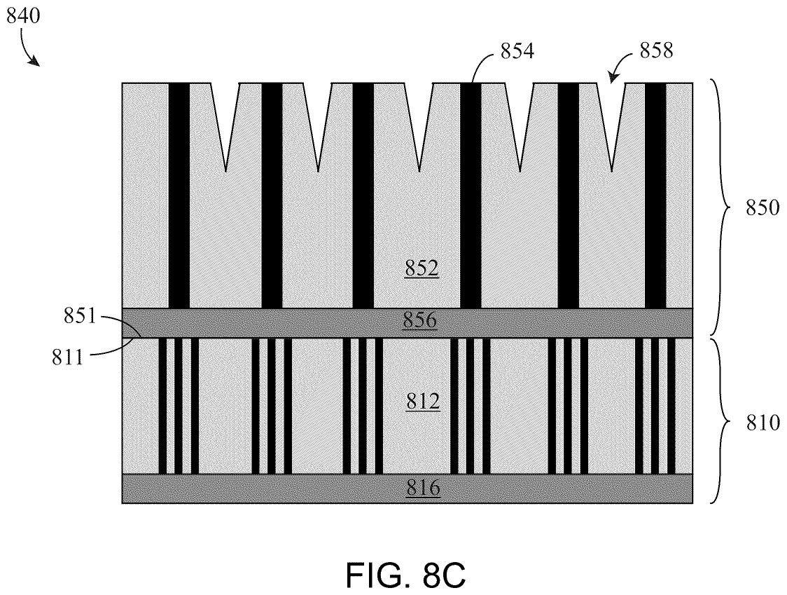

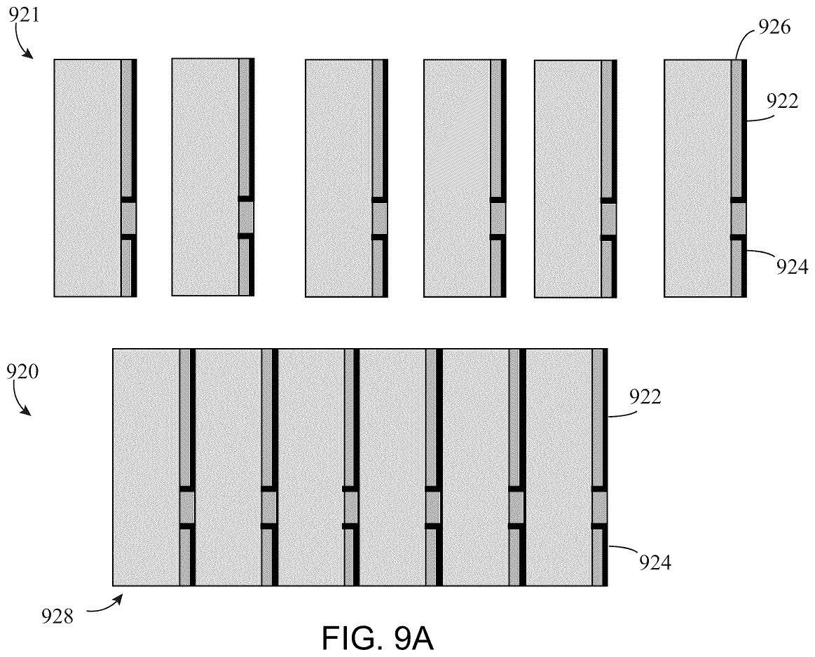

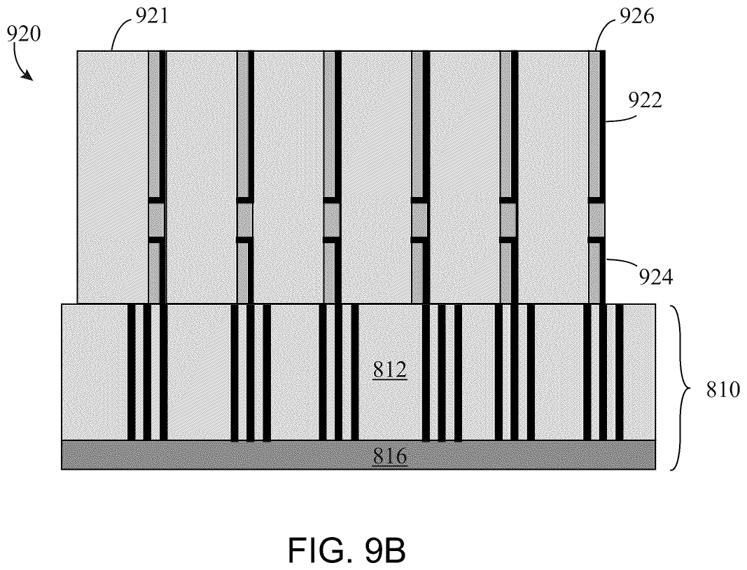

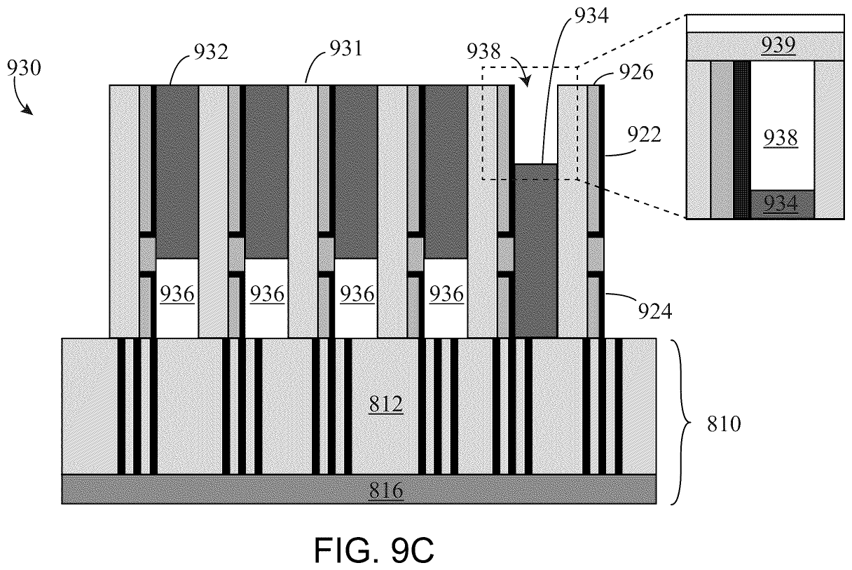

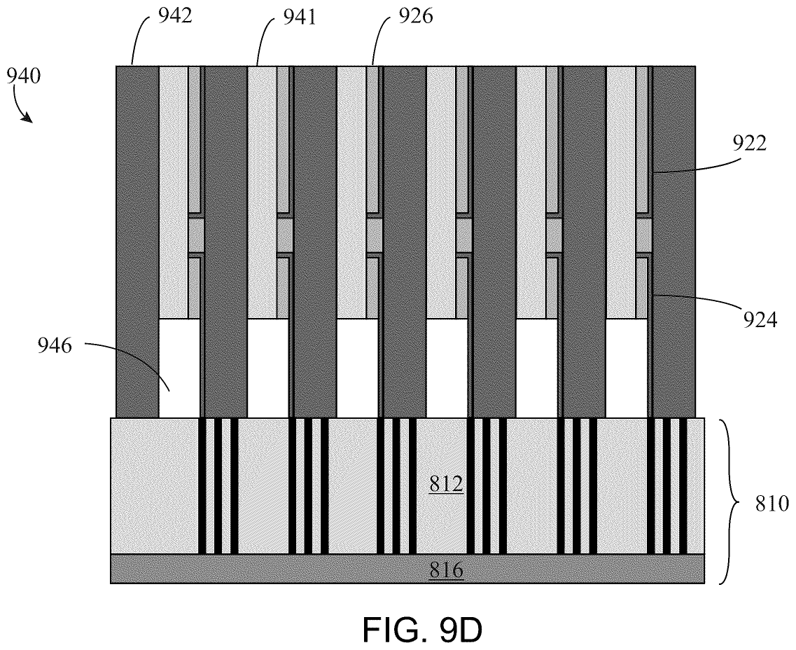

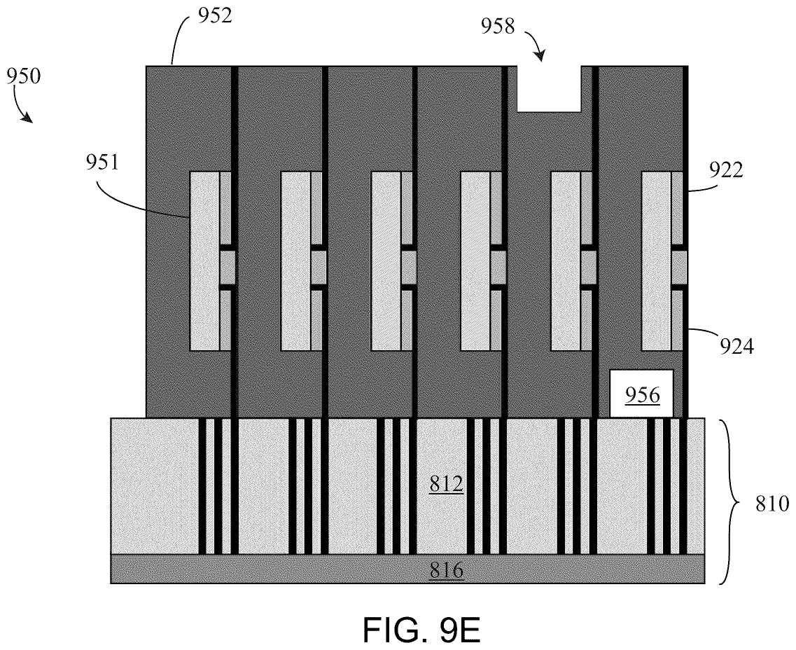

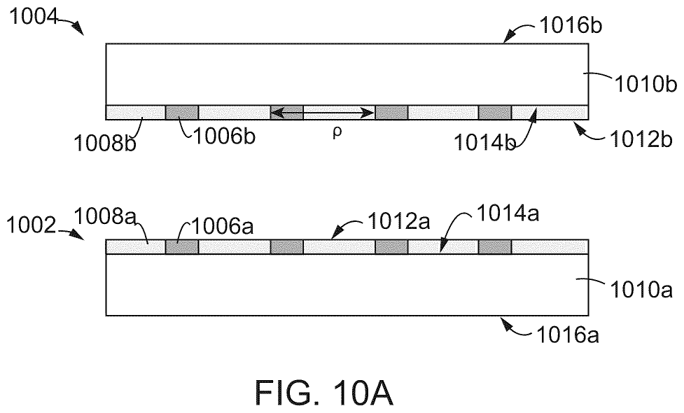

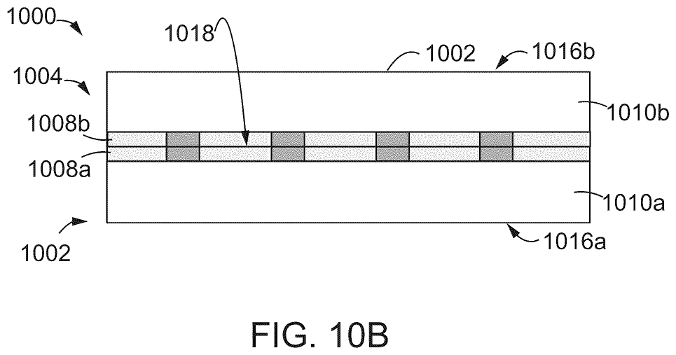

FIGS. 1-7D relate to various aspects of a cooling assembly, which may be applied towards cooling an active power delivery chip (e.g., second semiconductor device) attached to a chip (e.g., first semiconductor device). FIGS. 8A-8C may schematically illustrate various embodiments of an active power delivery chip attached to a chip (e.g., second semiconductor device 820 or 850 attached to a first semiconductor device 810). In some embodiments, a cold plate may be attached to the active power delivery chip (e.g., cold plate 830 attached to second semiconductor device 820 as shown in FIG. 8B). In some embodiments, an active power delivery chip may include coolant channels (e.g., second semiconductor device 850 with coolant channels 858 as shown in FIG. 8C). FIG. 9A may schematically illustrate bonding a stack of active power delivery chips to each other (e.g., apparatus 920 of bonded second semiconductor devices 921). FIGS. 9B-9E may schematically illustrate various embodiments of an apparatus or stack (e.g., stack of active power delivery chips or active power delivery chips and spacers) attached to a chip (e.g., apparatus 920, 930, 940, 950 comprising second semiconductor devices 921, 931, 941, 951 attached to first semiconductor device 810). In some embodiments, two active power delivery chips in the stack may be separated by a spacer, and an edge of the spacer may define a cooling channel facing towards or away from the chip (e.g., second semiconductor devices 941 separated by spacer 932 and coolant channels 936 and 938 facing towards or away from the first semiconductor device 810 as shown in FIG. 9C). In some embodiments, an active power delivery chip is between two spacers, and an edge of the active power delivery chip may define a coolant channel facing towards the chip (e.g., second semiconductor device 941 between two spacers 942 and coolant channel 946 facing the first semiconductor device 810 as shown in FIG. 9D). In some embodiments, the active power delivery chip may be embedded in a spacer, and a coolant channel may be disposed in the spacer (e.g., second semiconductor device 820 embedded in spacer 952 and coolant channel 956 or 958 as shown in FIG. 9E). FIGS. 10A-10B illustrate a hybrid bonding method for bonding substrates (e.g., semiconductor devices to semiconductor devices, cold plates to semiconductor devices, spacers to semiconductor devices, etc.).

Although channels of a particular shape, number, or type (e.g., orientation, face up or face down) may be shown or described in embodiments the present disclosure, any suitable shape, number, or channel type channel may be used. Although a particular number of vias in the semiconductor devices (e.g., chips, power delivery chips, etc.) or cold plates may be shown or described in the present disclosure, any suitable number of vias may be used. Although semiconductor devices (e.g., chips, power delivery chips, etc.) and cold plates may be shown or described in embodiments of the present disclosure as being attached using direct bonding or hybrid bonding, any suitable technique or method (e.g., solder, adhesive, etc.) may be used.

FIG. 1 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and the device stack 15 to the heat spreader 18. The device package 10 is thermally coupled to the heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 1 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirably transferred from the first device 14 having a high heat flux, such as a central processing unit (CPU) or a graphical processing unit (GPU), to the device stack 15 having low heat flux, such as memory, through the heat spreader 18.

For example, as shown in FIG. 1, each device package component and the respective interfacial boundaries therebetween have a corresponding thermal resistance that forms heat transfer path 26 (illustrated by arrow 26 in FIG. 1). The right-hand side of FIG. 1 illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26, and R5 may account for 5% or more. R1 of the first device 14 and R2, R4, R6, and R8 of the interfaces account for the remaining cumulative thermal resistance. Accordingly, embodiments described herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures below.

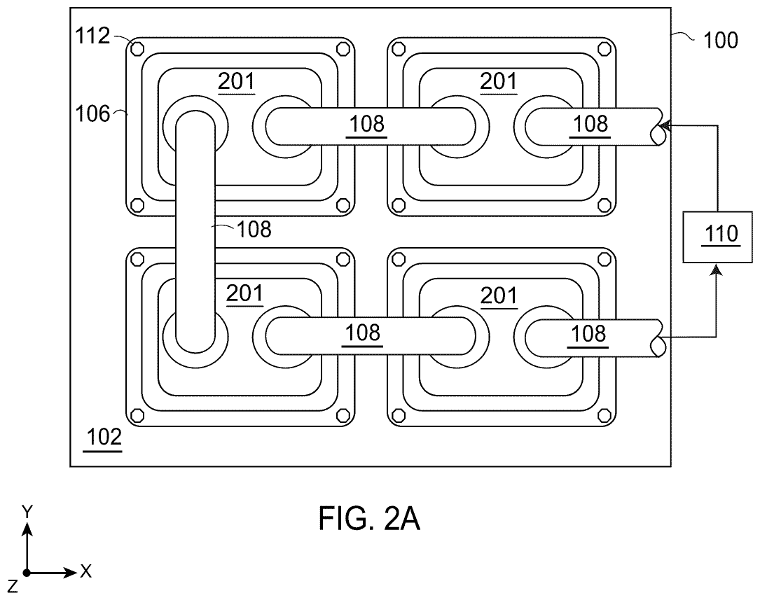

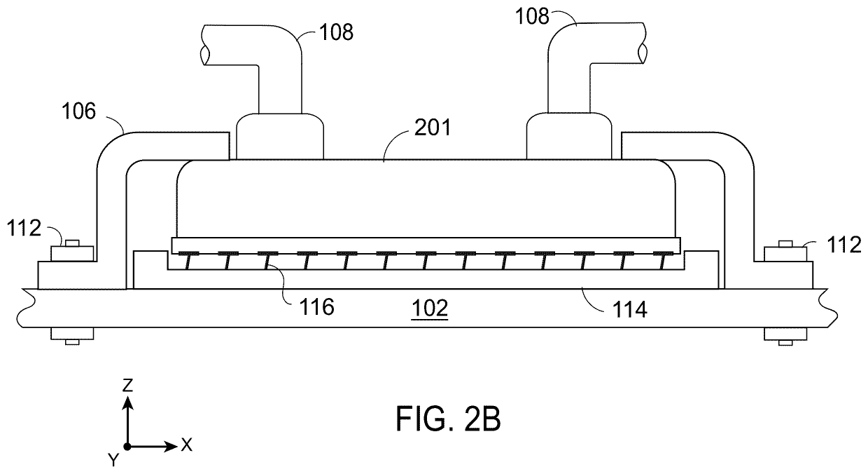

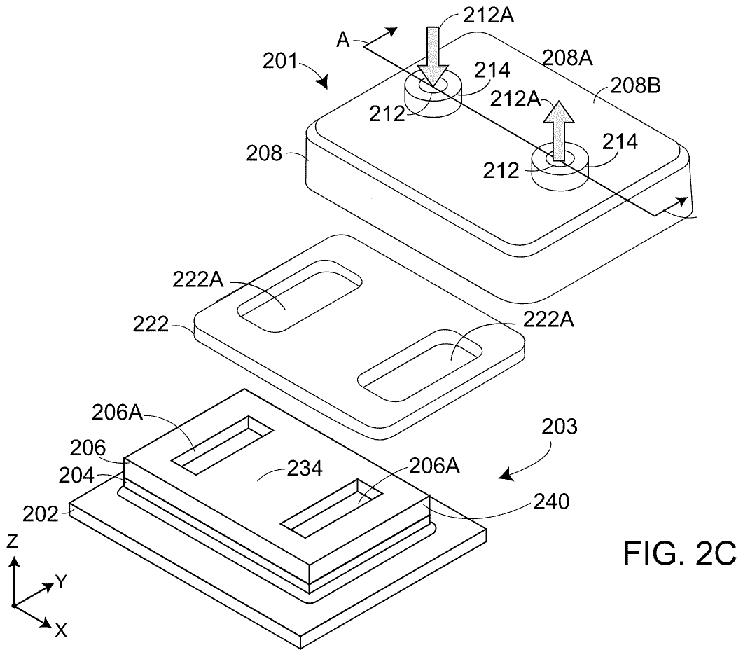

FIG. 2A is a schematic plan view of an example of a system panel 100, in accordance with embodiments of the present disclosure. Generally, the system panel 100 includes a printed circuit board (PCB) 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase, e.g., liquid, vapor, gas, or combinations thereof, and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel, and the coolant source 110 may include or further include a compressor (not shown) for condensing the received vapor to a liquid form.

FIG. 2B is a schematic partial sectional side view of a portion of the system panel 100 of FIG. 2A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112, e.g., compression screws, collectively configured to exert a relatively uniform downward force on the upward facing edges of the device package 201. The uniform downward force ensures proper pin contact between the device package 201 and the socket 114.

FIG. 2C is a schematic exploded isometric view of an example device package 201, in accordance with embodiments of the present disclosure. Generally, the device package 201 includes a package substrate 202, an integrated cooling assembly 203 disposed on the package substrate 202, and a package cover 208 disposed on a peripheral portion of the package substrate 202. Suitable materials that may be used in the package cover 208 include copper, aluminum, metal alloys, etc. The package cover 208 extends over the integrated cooling assembly 203 so that the integrated cooling assembly 203 is disposed between the package substrate 202 and the package cover 208. The integrated cooling assembly 203 typically includes a semiconductor device 204 and a cold plate 206 bonded to the semiconductor device 204. Although the lateral dimensions (or footprint) of the cold plate 206 are shown to be the same or similar to the lateral dimensions (or footprint) of the semiconductor device 204, the footprint of the cold plate 206 may be smaller or larger in one or both directions when compared to the footprint of the semiconductor device 204.

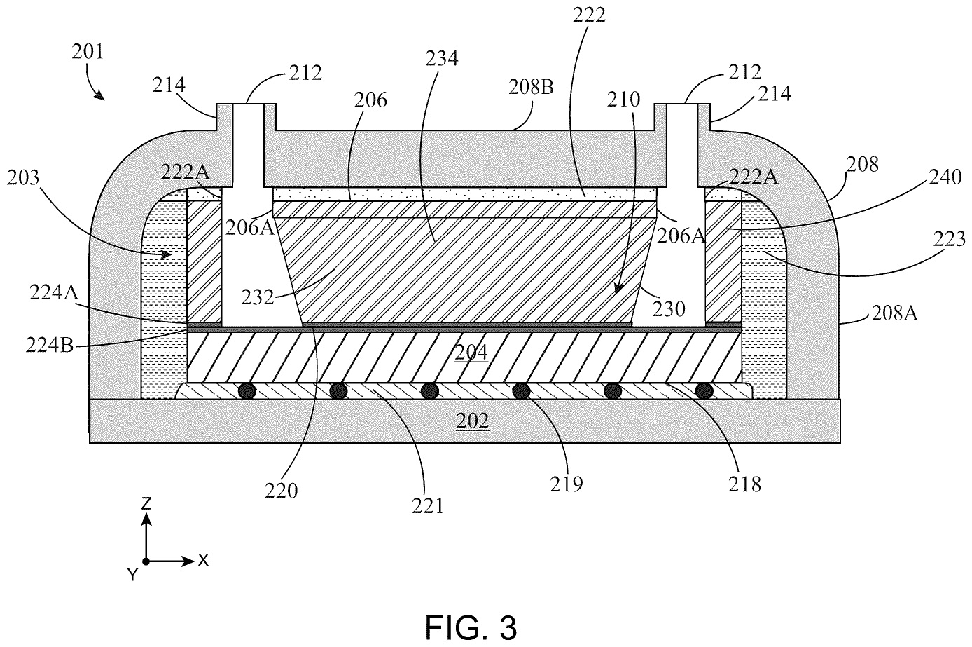

As shown, the device package 201 further includes a sealing material layer 222 that forms a coolant fluid impermeable barrier between the package cover 208 and the integrated cooling assembly 203 that prevents leaking of the coolant fluid outside of the cooling assembly and prevents coolant fluid from reaching an active side 218 (discussed below in relation to FIG. 3) of the semiconductor device 204 and causing damage thereto. In some embodiments, the sealing material layer 222 comprises an adhesive material that reliably attaches the package cover 208 to the integrated cooling assembly 203. In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g., solder. In other embodiments, the sealing material layer 222 is formed from a molding compound, e.g., a thermoset resin, that when polymerized, forms a hermetic seal between the package cover 208 and the cold plate 206. Here, the coolant fluid is delivered to the cold plate 206 through openings 222A disposed through the sealing material layer 222. As shown, the openings 222A are respectively in registration and fluid communication with inlet and outlet openings 212 of the package cover 208 thereabove and inlet and outlet openings 206A in the cold plate 206 therebelow.

It will be understood that the openings are shown in a section view. The openings may have any cross-sectional shape that allows fluid to flow therethrough (e.g., rectangular, square, hexagonal or circular cross-sections). For example, the inlet and outlet openings 206A of the cold plate 206 may form an elongated shape extending from one side of the cold plate 206 to another side of the cold plate 206. For example, the inlet and outlet openings 206A may form any shape having a length greater than a width in the X-Y plane (e.g., a rectangular or a trapezoidal shape). A shape in the X-Y plane of the openings 222A disposed through the sealing material layer 222 may be substantially the same as the shape of the inlet and outlet openings 206A of the cold plate 206 in the same place. Furthermore, it will be understood that references to an opening throughout the present disclosure refer to an opening defined by a sidewall (e.g., opening sidewall), unless otherwise indicates.

In some embodiments, gaps formed between the inside walls of the package cover 208 and the integrated cooling assembly 203 may be filled (partially or completely) with a molding material 223. The molding material 223 may encapsulate the integrates cooling assembly 203 to improve structural stability, for example.

The package substrate 202 can include a rigid material, such as an epoxy or resin-based laminate, that supports the integrated cooling assembly 203 and the package cover 208. The package substrate 202 may include conductive features disposed in or on the rigid material that electrically couples the integrated cooling assembly 203 to a system panel, such as the PCB 102.

FIG. 3 is a schematic sectional view in the X-Z plane of the device package 201 taken along line A-A′ of FIG. 2C. As illustrated in FIG. 3, the semiconductor device 204 includes the active side 218 that includes device components, e.g., transistors, resistors, and capacitors, formed thereon or therein, and a non-active side, here the semiconductor device backside 220, opposite the active side 218. As shown, the active side 218 is positioned adjacent to and facing towards the package substrate 202. The active side 218 may be electrically connected to the package substrate 202 by use of conductive bumps 219, which are encapsulated by a first underfill layer 221 disposed between the semiconductor device 204 and the package substrate 202. The first underfill layer 221 may comprise a cured polymer resin or epoxy, which provides mechanical support to the conductive bumps 219 and protects against thermal fatigue. In some embodiments, the active side 218 may be electrically connected to another package substrate, another active die, or another passive die (e.g., interposer) using hybrid bonding or conductive bumps 219. For example, the package substrate 202 may be a semiconductor substrate, a semiconductor interposer, a glass substrate, a glass interposer, a PCT or a combination thereof. The cold plate 206 may be disposed above the package substrate 202 with the semiconductor device 204 disposed therebetween. For example, the semiconductor device 204 (and the first underfill layer 221) may be disposed between the cold plate 206 and the package substrate 202. In some embodiments, the cold plate 206 may be disposed directly on the package substrate 202.

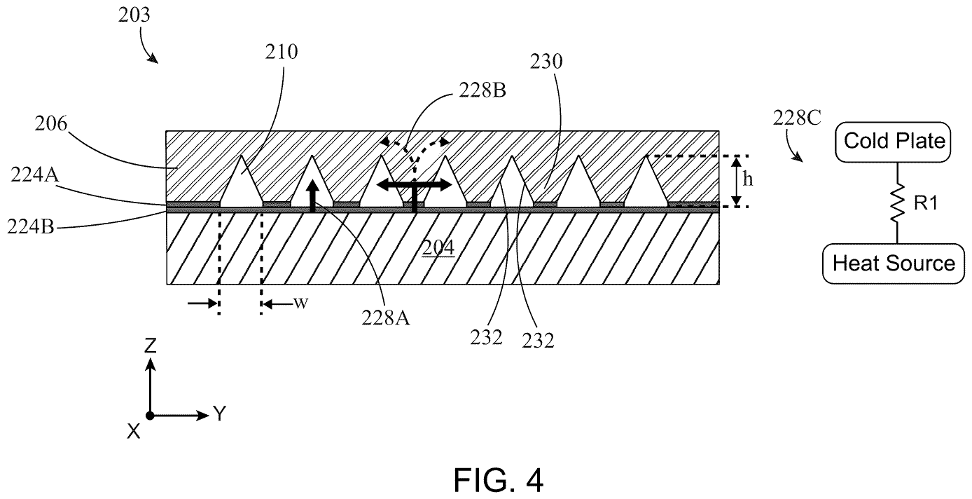

Here, the cold plate 206 comprises a top portion 234 and a sidewall 240 (e.g., a perimeter sidewall defining a perimeter of the cold plate 206) extending downwardly from the top portion 234 to the backside 220 of the semiconductor device 204. The top portion 234, the perimeter sidewall 240, and the backside 220 of the semiconductor device 204 collectively define a coolant channel 210 therebetween. The cold plate 206 comprises cavity dividers 230 extending downwardly from the top portion 234 towards the backside 220 of the semiconductor device 204. The cavity dividers 230 may alternatively be referred to as support features 230, which provide structural support to the integrated cooling assembly 203. The cavity dividers 230 may extend laterally and in parallel between an inlet opening 206A of the cold plate 206 and an outlet opening 206A of the cold plate 206 to define plural coolant channels 210 therebetween. It should be appreciated that, the cold plate 206 may comprise one cavity divider 230 which forms two coolant channels (e.g., one coolant channel on either side of the cavity divider 230) by means of the cavity divider 230 and portions of the perimeter sidewall 240. More specifically, coolant channels 210 may be formed between the cavity divider 230 and a portion of the perimeter sidewall 240 extending parallel to or in the same general direction as the cavity divider 230. Alternatively, in other embodiments, the cold plate 206 may comprise plural cavity dividers 230, for example two cavity dividers, five cavity dividers, or six cavity dividers (as illustrated in FIG. 4). In such examples, the cold plate 206 comprises more than two coolant channels 210, for example three coolant channels, four coolant channels, seven coolant channels, or more, defined between the cavity dividers 230 and/or the cavity divider(s) 230 and the perimeter sidewall 240. In some embodiments, at least one of the cavity dividers 230 may extend discontinuously between the inlet opening 206A and the outlet opening 206A (in the X-axis direction) to form a discontinuous cavity divider. A discontinuous cavity divider may be formed of plural segments between which coolant fluid may flow. The segments of a discontinuous cavity divider may have the same or different lengths in the X-axis direction. One or more segments may form a post.

The cavity dividers 230 comprise cavity sidewalls 232 which form surfaces of corresponding coolant channels 210. In embodiments where plural cavity dividers 230 extend in parallel to each other, cavity sidewalls 232 of adjacent cavity dividers 230 are opposite (e.g., facing) each other. In embodiments comprising a single cavity divider 230, a first cavity sidewall may be opposite (e.g., face) a first portion of the perimeter sidewall 240 extending parallel to and facing the first cavity sidewall. A second cavity sidewall may be opposite (e.g., face) a second portion of the perimeter sidewall 240 extending parallel to and facing the second cavity sidewall. The first portion of the perimeter sidewall 240 may be an opposite side of the cold plate 206 to the second portion of the perimeter sidewall 240. For example, in embodiments where the cold plate 206 is rectangular, first and second opposing sides of the rectangular cold plate 206 form the first and second portions of the perimeter sidewall 240.

The cavity dividers 230 may be continuous cavity dividers which extend continuously (e.g., in the X-axis direction) between the inlet opening 206A and the outlet opening 206A of the cold plate 206.

With reference to FIG. 3, coolant channels 210 may be defined by:
the backside 220 of the semiconductor device 204, which forms lower coolant channel surfaces;
portions of the perimeter sidewall 240 extending in the Y-axis direction, which form end surfaces of the coolant channels 210;
the cavity sidewalls 232, which form inner surfaces of the coolant channels 210 in the X-axis direction; and
portions of the perimeter sidewall 240 extending in the X-axis direction, which form outer surfaces of the coolant channels 210 in the X-axis direction.

As shown in FIG. 4 and described in further detail below, the cavity sidewalls 232 can be formed at an acute angle with respect to the backside 220 of the semiconductor device 204 such that upper portions of opposing (e.g., facing) cavity sidewalls 232 meet. Therefore, the cavity sidewalls 232 and the backside 220 of the semiconductor device 204 collectively define a triangular cross-section of the coolant channel 210. However, it will be understood that the coolant channel 210 may be formed with different shaped cross-sections. For example, one or more coolant channels may be formed with trapezoidal, rectangular, or semi-circular cross-section, or a combination thereof.

In some embodiments, the backside 220 of the semiconductor device 204 comprises a corrosion protective layer (not shown). The corrosion protective layer may be a continuous layer disposed across the entire backside 220 of the semiconductor device 204, such that the cold plate 206 is attached thereto. Beneficially, the corrosion protective layer provides a corrosion-resistant barrier layer, thus preventing undesired corrosion of the semiconductor device 204 (e.g., the semiconductor substrate material which might otherwise be in direct contact with coolant fluid flowing through a coolant chamber volume 210).

One or more coolant chamber volumes may include one or more coolant channels. The coolant channels may extend between a single inlet opening and a single outlet opening of the cold plate 206, such that the coolant chamber volume(s) and/or coolant channel(s) share the same inlet and outlet openings. In other embodiments, multiple inlet and/or outlet openings may be coupled to the coolant chamber volume(s).

In embodiments having plural coolant chamber volumes and/or plural coolant channels, each coolant chamber volume and/or coolant channel may be connected between a separate inlet opening and a separate outlet opening. In such embodiments, the coolant fluid may be directed to the separate inlet openings and from the separate outlet openings using a manifold disposed above the openings in the Z-axis direction. In some embodiments, a gasket may be used to seal a gap between the manifold and the cold plate inlet/outlet openings. The gasket may be made of rubber (e.g., neoprene, nitrile, ethylene propylene diene monomer, or silicon rubber) or similar such material. For example, the gasket may be an o-ring. The gasket may be attached between a lower surface of the manifold and an upper surface of the cold plate facing the manifold using an adhesive. The gasket may provide a water tight seal to direct coolant fluid from the manifold into the cold plate inlet/outlet openings while preventing coolant fluid from leaking onto exterior surfaces of the integrated cooling assembly 203. In some embodiments, the manifold is attached to one or more cold plates using one or more corresponding gaskets.

Referring to FIG. 4, a height h in the Z-axis direction of the coolant chamber volume(s) and or coolant channel(s) may be greater than 100 μm, 100 μm-1000 μm, or 100 μm-700 μm. A width w in the Y-axis direction of each coolant channel 210 may be greater than 100 μm, 100 μm-1000 μm, or 100 μm-700 μm. For example, the width of each coolant channel 210 may be greater than the height h thereof. In some embodiments, the width w of a coolant channel 210 may, at the widest portion, which may be taken as a base of the triangular shape of the coolant chamber channels 210 shown in FIG. 4, range from 0.2 mm to 5 mm. More specifically, the width w of a coolant channel 210 may range from 0.5 to 1.5 mm. The width w of the coolant chamber volumes(s) and/or coolant channel(s) may also be between 1 and 5 mm.

A cross-section of the coolant chamber volume(s) and/or coolant channel(s) in the Y-Z plane is wide enough to allow for a pressure drop of 0 -20 psi, 3-15 psi, or 4-10 psi.

In some embodiments, preparing a desired surface roughness of the sidewalls of the coolant chamber volume(s) and/or coolant channels may include depositing an organic layer on a photoresist layer after cold plate features have been etched to form a micro-masking layer, such as between 1 to 30 nm. The micro-masking layer may be dry etched to form the desired surface roughness, such as between 0.1 to 3.0 nm. Advantageously, providing sidewalls with surface roughness increases the likelihood of fluid being directed towards and contacting the backside 220 of the semiconductor device 204 (e.g., by disrupting a hydrodynamic boundary layer of fluid between the sidewall and the coolant fluid).

With reference to FIG. 3, the cold plate 206 is attached to the backside 220 of the device 204 without the use of an intervening adhesive. For example, the cold plate 206 may be directly bonded to the backside 220 of the device 204, such that the cold plate 206 and the backside 220 of the device 204 are in direct contact. For example, in some embodiments, one or both of the cold plate 206 and the backside 220 of the semiconductor device 204 may comprise a dielectric material layer, e.g., a first dielectric material layer 224A and a second dielectric material layer 224B respectively, and the cold plate 206 is directly bonded to the backside 220 of the semiconductor device 204 through bonds formed between the dielectric material layers 224A, 224B. In some embodiments, one of the cold plate 206 or the backside 220 of the semiconductor device 204 may comprise a thin bonding dielectric layer (e.g., silicon nitride, etc.) and other element(s) may not include any such explicit bonding dielectric layer (or can have only a native oxide layer). The first and second dielectric material layers 224A, 224B may be continuous or non-continuous. For example, the first dielectric material layer 224A may be disposed only on lower surfaces of the cold plate 206 facing the backside 220 of the semiconductor device 204. With reference to FIG. 4, described below, portions of the first dielectric material layer 224A may be disposed only on lower surfaces of the cavity dividers 230 (e.g. support features 230) and the perimeter sidewall 240. Beneficially, directly bonding the cold plate 206 to the semiconductor device 204, as described above, reduces the thermal resistance therebetween and increases the efficiency of heat transfer from the semiconductor device 204 to the cold plate 206. In particular, thermal resistance is reduced by directly bonding lower surfaces of the cavity dividers 230 facing the semiconductor device 204 to the backside 220 of the semiconductor device 204.

FIG. 4 is a schematic sectional view in the Y-Z plane of the integrated cooling assembly 203. In FIG. 4, the cold plate 206 comprises a patterned side that faces towards the semiconductor device 204 and an opposite side that faces towards the package cover 208 (not shown). The patterned side comprises a coolant chamber volume having plural coolant channels 210, which extend laterally (along the X-axis direction in FIG. 4) between the inlet and outlet openings of the cold plate 206. Each coolant channel 210 comprises cavity sidewalls that define a corresponding coolant channel 210. Portions of the cold plate 206 between the cavity sidewalls 232 form the support features 230 (e.g., cavity dividers 230). The support features 230 (e.g., cavity dividers 230) provide structural support to the integrated cooling assembly 203 and disrupt laminar fluid flow (e.g., due to surface roughness of the sidewalls) at the interface of the coolant and the device backside 220, resulting in increased heat transfer therebetween. Furthermore, by introducing plural coolant channels 210 to define separate coolant flow paths, an internal surface area of the cold plate 206 is increased, which further increases the efficiency of heat transfer.

In FIG. 4, arrows 228A and 228B illustrate two different heat transfer paths in the integrated cooling assembly 203. A first heat transfer path illustrated by arrow 228A shows heat generated by the semiconductor device 204 transferring directly from the semiconductor material of the semiconductor device 204 to coolant fluid flowing through the cold plate 206. A second heat transfer path illustrated by arrows 228B shows heat generated by the semiconductor device 204 being transferred from semiconductor material (e.g., silicon material) of the semiconductor device 204 to semiconductor material (e.g., silicon material) of the cold plate 206 structure, propagated throughout the semiconductor material of the cold plate 206 structure (shown as dashed lines), and being transferring into coolant fluid flowing through the cold plate 206. A thermal resistance of the first and second heat transfer paths 228A, 228B is illustrated by heat transfer path 228C, which is shown as thermal resistance R1 between a heat source and a cold plate. Here, R1 is the thermal resistance of the bulk semiconductor material of the semiconductor device 204. It can be seen that the heat transfer path 228C of the integrated cooling assembly 203 is reduced compared to the heat transfer path 26 of the device package 10 of FIG. 1, due to the direct bonding discussed above.

In some embodiments, the cold plate 206 may be attached to the semiconductor device 204 using a hybrid bonding technique, where bonds are formed between the dielectric material layers 224A, 224B and between metal features, such as between first metal pads and second metal pads, disposed in the dielectric material layers 224A, 224B. Advantageously, by using hybrid bonding techniques, interconnections may be formed between the cold plate 206 and the semiconductor device 204 using the first and second metal pads.

Suitable dielectrics that may be used as the dielectric material layers 224A, 224B include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers 224A, 224B are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometers or less, 1 micrometer or less, 500 nm or less, such as 100 nm or less, or 50 nm or less. The dielectric layer material and thickness may be optimized for lower thermal resistance between the semiconductor device and the cold plate.

The cold plate 206 may be formed of any suitable material that has sufficient structural strength to withstand the desired pressures of coolant flowing into the coolant chamber volume 210. For example, the cold plate 206 may be formed of semiconductor material like silicon or other materials like glass. In other examples, the cold plate 206 may be formed of a material selected from a group comprising polymers, metals, ceramics, or composites thereof. In some embodiments, the cold plate 206 may be formed of stainless steel (e.g., from a stainless steel metal sheet) or a sapphire plate.

In some embodiments, the cold plate 206 may be formed of a bulk material having a substantially similar CTE to the bulk material of the substrate 202 and/or the semiconductor device 204, where the CTE is a fractional change in length of the material (in the X-Y plane) per degree of temperature change. In some embodiments, the CTEs of the cold plate 206, the substrate 202, and/or the semiconductor device 204 are matched so that the CTE of the substrate 202 and/or the semiconductor device 204 is within about +/−20% or less of the CTE of the cold plate 206, such as within +/−15% or less, within +/−10% or less, or within about +/−5% or less when measured across a desired temperature range. In some embodiments, the CTEs are matched across a temperature range from about −60° C. to about 100° C. or from about −60° C. to about 175° C. In one example embodiment, the matched CTE materials each include silicon.

In some embodiments, the cold plate 206 may be formed of a material having a substantially different CTE from the semiconductor device 204, e.g., a CTE mismatched material. In such embodiments, the cold plate 206 may be attached to the semiconductor device 204 by a compliant adhesive layer (not shown) or a molding material that absorbs the difference in expansion between the cold plate 206 and the semiconductor device 204 across repeated thermal cycles.

The package cover 208 shown in FIGS. 2C and 3 generally comprises one or more vertical or sloped sidewall portions 208A and a lateral portion 208B that spans and connects the sidewall portions 208A. The sidewall portions 208A may extend upwardly from a peripheral surface of the package substrate 202 to surround the device 204 and the cold plate 206 disposed thereon. The lateral portion 208B may be disposed over the cold plate 206 and is typically spaced apart from the cold plate 206 by a gap corresponding to the thickness of the sealing material layer 222. The sealing material may be an adhesive or a gasket. In some embodiments, instead of or as well as the sealing material layer 222, a gasket may be used to seal a gap between the package cover 208 and the cold plate inlet/outlet openings. The gasket may be made of rubber (e.g., neoprene, nitrile, ethylene propylene diene monomer, or silicon rubber) or similar such material. For example, the gasket may be an o-ring. The gasket may be attached between a lower surface of the package cover 208 and an upper surface of the cold plate facing the package cover 208 using an adhesive. The gasket may provide a water tight seal to direct coolant fluid from the package cover 208 into the cold plate inlet/outlet openings while preventing coolant fluid from leaking onto exterior surfaces of the integrated cooling assembly 203. In some embodiments, the package cover 208 is attached to one or more cold plates using one or more corresponding gaskets.

Coolant is circulated through the coolant chamber volume 210 through the inlet and outlet openings 212 of the package cover 208 formed through the lateral portion 208B. The inlet and outlet openings 206A of the cold plate 206 may be in fluid communication with the inlet and outlet openings 212 of the package cover 208 through the inlet and outlet openings 222A formed in the sealing material layer 222 disposed therebetween. In certain embodiments, coolant lines 108 (FIGS. 2A-2B) may be attached to the device package 201 by use of connector features formed in the package cover 208, such as threads formed in the sidewalls of the inlet and outlet openings 212 of the package cover 208 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 206 and the semiconductor device 204 therebelow. In some embodiments, the package cover 208 is formed of a thermally conductive metal, such as aluminum or copper. In such embodiments, the package cover 208 functions as a heat spreader that redistributes heat from one or more electronic components of the semiconductor device 204. In some embodiments, the package cover 208 and/or a manifold (such as the manifold discussed above) may consist of or comprise a thermally insulating material or materials. In such embodiments, the package cover 208 and/or the manifold may function as a thermal insulator to retain heat or cold. In some embodiments, the package cover 208 and/or the manifold may be insulating to minimize or reduce the flow of thermal energy (e.g., thermal flux) between components (e.g., semiconductor devices, semiconductor device stacks, device packages, etc.). For example, the package cover 208 and/or the manifold may minimize or reduce the flow of thermal energy between a first semiconductor device and a second semiconductor device. In another example, the package cover 208 and/or the manifold may minimize or reduce the flow of thermal energy between a first semiconductor device stack and a second semiconductor device stack. In another example, the package cover 208 and/or the manifold may minimize or reduce the flow of thermal energy between a first device package and a second device package. In another example, the package cover 208 and/or the manifold may minimize or reduce the flow of thermal energy between a semiconductor device and a semiconductor device stack. In another example, the package cover 208 and/or the manifold may minimize or reduce the flow of thermal energy between a semiconductor device of a device package and a second device package.

It should be noted that the direction in which the coolant fluid flows through the cold plate 206 may be controlled depending on the relative locations of the inlet and outlet openings. For example, the coolant fluid may flow from left to right in the device package 201 of FIG. 3 when the inlet openings 212, 222A, 206A of the package cover 208, the sealing material layer 222, and the cold plate 206, respectively, are located on the left-hand side of the device package 201 and the outlet openings 212, 222A, 206A of the package cover 208, the sealing material layer 222, and the cold plate 206, respectively, are located on the right-hand side of the device package 201. Alternatively, the coolant fluid may flow from right to left in the device package 201 illustrated in FIG. 3 when the outlet openings 212, 222A, 206A of the package cover 208, the sealing material layer 222, and the cold plate 206 are located on the left-hand side of the device package 201 and the inlet openings 212, 222A, 206A of the package cover 208, the sealing material layer 222, and the cold plate 206 are located on the right-hand side of the device package 201. Although only one set of inlet and outlet openings is shown and described here, additional inlet and outlet openings may also be provided at various locations on the package cover 208, the sealing material layer 222, and the cold plate 206.

An example flow path of the coolant fluid through the coolant chamber volume 210 may be as follows:
1. Coolant fluid enters the coolant chamber volume 210 through the inlet openings 212, 222A, and 206A.
2. Coolant fluid flows across the inside surfaces of the cold plate 206 and absorbs heat generated by the semiconductor device 204, which has dissipated into the cold plate 206 structure. The coolant fluid may also flow directly across the backside 220 of the semiconductor device 204 to absorb heat energy directly from the semiconductor device 204. The coolant chamber volume 210 may additionally have various channels formed to direct the coolant fluid flow from inlet opening(s) to outlet opening(s) and facilitate heat extraction from the semiconductor device 204 by the coolant fluid. In some embodiments, the coolant fluid may be in direct contact with the backside 220 of the semiconductor device 204 or via one or more substrate or layers between the coolant fluid or backside 220 of the semiconductor device 204.
3. Coolant fluid exits the coolant chamber volume 210 through outlet openings 212, 222A, and 206A.

It will be understood from the above flow path that heat is extracted without introducing an unnecessary thermal resistance (e.g., a TIM disposed between the backside 220 of the semiconductor device 204 and the cold plate 206) between the backside 220 of the semiconductor device 204 and the cold plate 206.

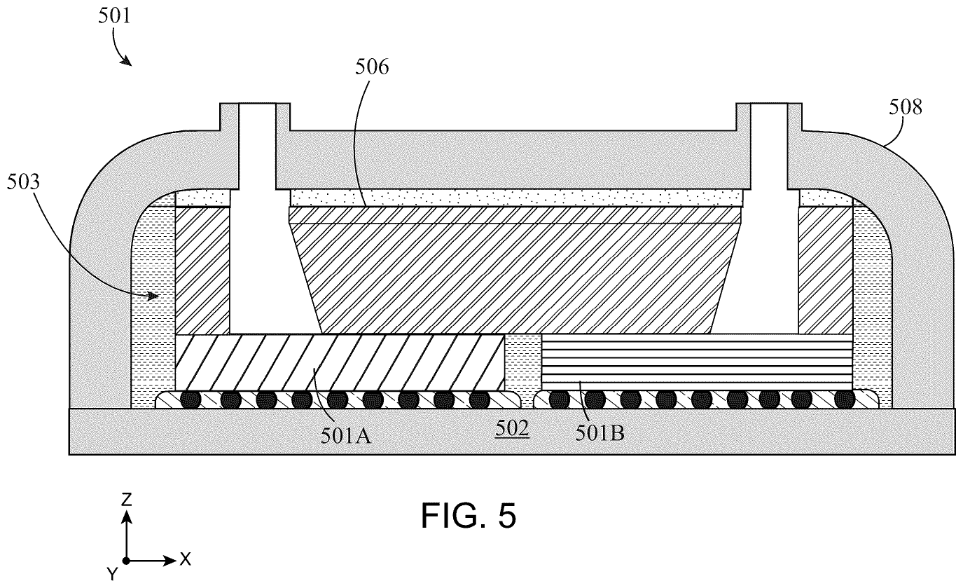

FIG. 5 is a schematic side sectional view in the X-Z plane of an example of a multi-component device package 501 that includes a cold plate 506 directly bonded to the backside surfaces of two or more devices 501A, 501B. The multi-component device package 501 may be similar to the device package 201 described above, and therefore the description of similar features is omitted for brevity. In some embodiments, the two or more devices 501A and 501B are singulated from reconstituted wafers and then bonded to the cold plate 506. As shown, the device package 501 includes a package substrate 502, an integrated cooling assembly 503 and a package cover 508. The integrated cooling assembly 503 may include a plurality of devices 501A (one shown) that may be singulated and/or disposed in a vertical device stack 501B (one shown). The cold plate 506 may be attached to each of the devices 501A and device stack 501B, e.g., by the direct bonding methods described herein or other methods including adhesive. In some embodiments, the device 501A may comprise a processor, and the device stack 501B may comprise a plurality of memory devices, such as a high bandwidth memory (HBM) comprising a bottom logic die and a plurality of memory (e.g., DRAM) dies stacked on the logic die. Here, the device 501A and the device stack 501B are disposed in a side-by-side arrangement on the package substrate 502 and are in electrical communication with one another through conductive elements formed in, on, or through the package substrate 502. Here, the cold plate 506 is sized to provide a bonding surface for attachment to both the device 501A and the device stack 501B but may otherwise be the same or substantially similar to other cold plates described herein. In some embodiments, the lateral dimensions (or footprint) of the cold plate 506 may be smaller or larger than the combined lateral dimensions (or footprint) of both the device 501A and the device stack 501B. In some embodiments, one or more sidewalls of the cold plate 506 may be aligned or offset to the vertical sidewalls of the device 501A and the device stack 501B (including inside or outside their footprint). In some embodiments, more than one cold plate 506 may be bonded. For example, separate cold plates may be bonded to the device 501A and the device stack 501B.

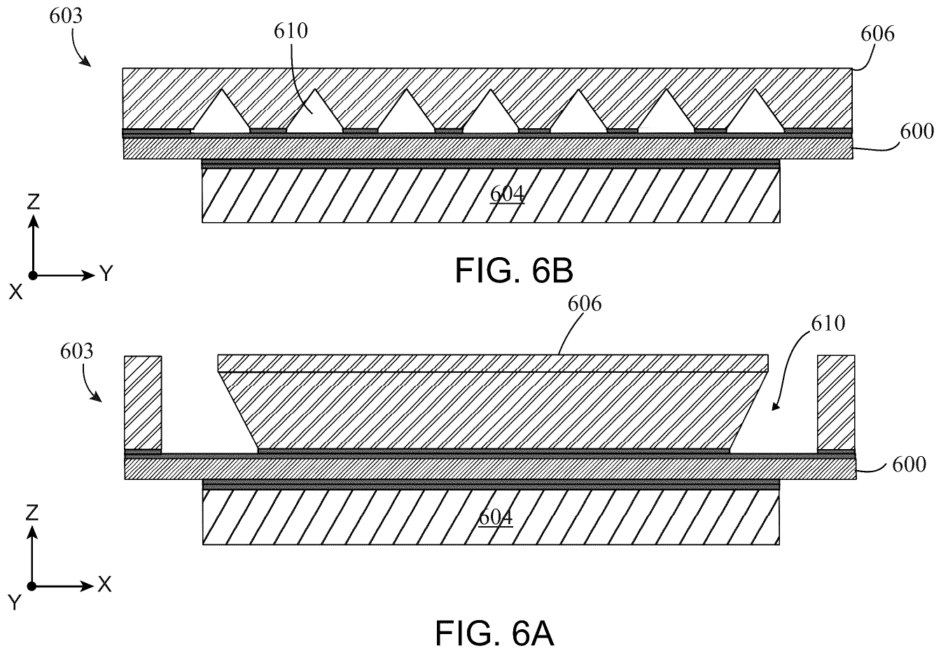

FIG. 6A is a schematic sectional view in the X-Z plane of an integrated cooling assembly 603 and FIG. 6B is a schematic sectional view in the Y-Z plane of the integrated cooling assembly 603, in accordance with embodiments of the present disclosure. The integrated cooling assembly 603 may be similar to the integrated cooling assembly 203 described above, and therefore the description of similar features is omitted for brevity.

In FIG. 6A, a width of a cold plate 606 in a first direction is greater than a width of a semiconductor device 604 the first direction. The first direction may be taken to be a direction perpendicular to a second direction in which perimeter sidewall extends. With reference to FIGS. 6A and 6B, the second direction is the Z-axis direction and the first direction is either the X-axis or the Y-axis direction. As shown, the width of the cold plate 606 is greater than the width of the semiconductor device 604 in both the X-axis direction and the Y-axis direction. In embodiments of FIGS. 6A and 6B where the semiconductor device 604 has a rectangular footprint, the cold plate 606 may extend beyond all four sidewalls of the semiconductor device 604. However, it will be understood that the width of the cold plate 606 may be greater than the width of the semiconductor device 604 in either the X-axis direction or the Y-axis direction.

In order to provide a cold plate 606 having a width greater than a width of the semiconductor device 604, a structural substrate 600 having substantially the same width (in the X-axis direction and/or the Y-axis direction) as the cold plate 606 is provided between the cold plate 606 and the semiconductor device 604. The structural substrate 600 provides structural rigidity to overhanging portions of the cold plate 606 and also closes portions of coolant channels 610 in the overhanging portions which would otherwise be exposed. The structural substrate 600 may be attached between the cold plate 606 and the semiconductor device 604 using direct bonding techniques described herein.

Advantageously, by increasing the width of the cold plate 606 in the X-axis direction and/or the Y-axis direction, as described above, additional coolant channels 610 may be introduced to the cold plate 606 in order to increase the efficiency of thermal cooling.

In some embodiments, only portions of coolant channels 610 in the overhanging portions may be closed by the structural substrate 600, while portions of coolant channels 610 vertically adjacent to the semiconductor device 604 may be exposed to a backside of the semiconductor device 604. For example, portions of coolant channels 610 vertically adjacent to the semiconductor device 604 may be exposed by etching openings in horizontally aligned portions of the structural substrate 600.

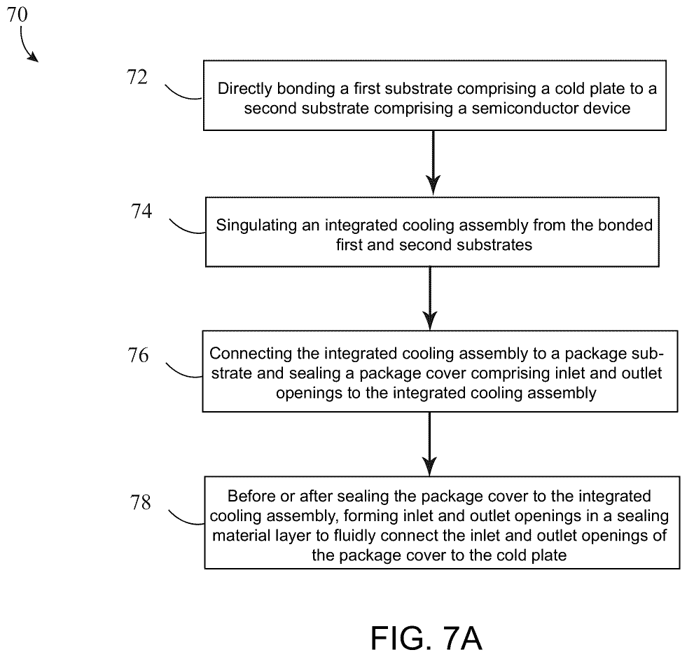

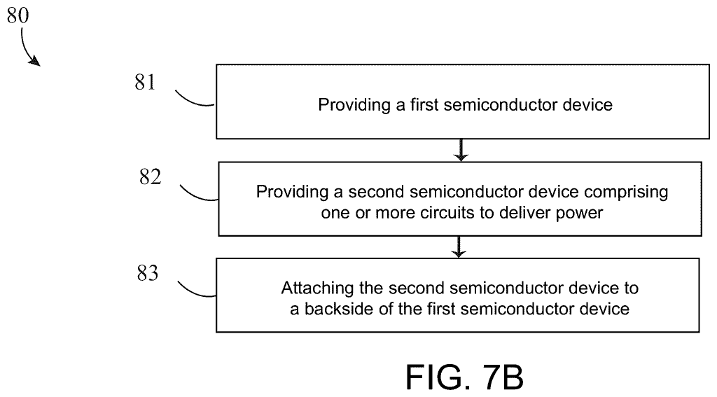

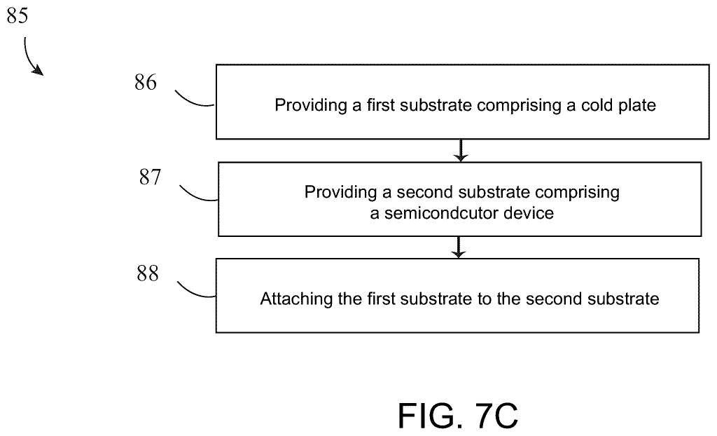

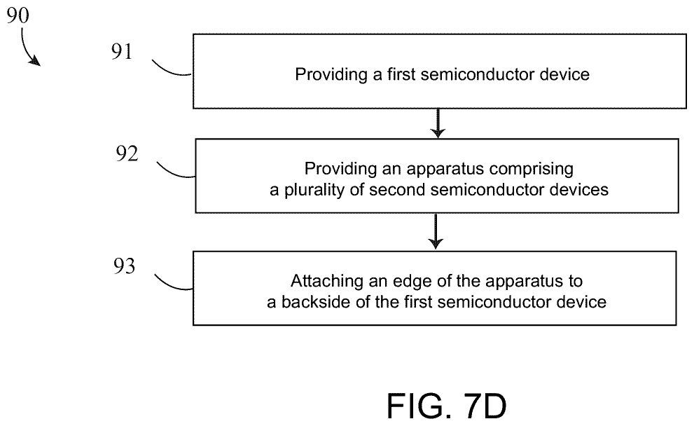

FIG. 7A is a flow diagram showing a method 70 of forming an integrated cooling assembly, according to embodiments of the present disclosure. Generally, the method 70 includes bonding a first substrate comprising one or more cold plates 206 to a second substrate comprising one or more semiconductor devices 204, and singulating one or more integrated cooling assemblies 203 from the bonded first and second substrates. For example, a wafer (bare or reconstituted wafer) comprising one or more cold plates 206 can be directly bonded to another wafer (bare or reconstituted wafer) comprising one or more semiconductor devices 204.

It will be understood that the first substrate may be a cold plate die or part of a wafer of cold plates. Further, the second substrate may be a semiconductor device die or part of a wafer of semiconductor devices 204. Therefore, the method 70 may include die-to-die direct bonding (e.g., cold plate die to semiconductor device die), wafer-to-die direct bonding (e.g., cold plate die to semiconductor device wafer, or cold plate wafer to semiconductor device die), and wafer-to-wafer direct bonding (e.g., cold plate wafer to semiconductor device wafer). It will be understood that the singulation step (discussed in relation to block 74, below) may not be required for a die-to-die direct bonding operation.

For simplicity, the following description is focused on forming one integrated cooling assembly 203 comprising one cold plate 206 and one semiconductor device 204. However, as mentioned above, in some embodiments, the first substrate may comprise plural cold plates 206 and the second substrate may comprise plural semiconductor devices 204, such that plural integrated cooling assemblies 203 may be formed from the first and second substrates.

At block 72, the method 70 includes directly bonding the first substrate (e.g., a monocrystalline silicon wafer) comprising a cold plate 206 to the second substrate (e.g., a monocrystalline silicon wafer) comprising a semiconductor device 204. By direct bonding, it is meant that the bond is effected without an intervening adhesive.

In some embodiments, the first substrate may be etched using a patterned mask layer formed on its surface to form features of the cold plate 206. An anisotropic etch process may be used, which uses inherently differing etch rates for the silicon material as between {100} plane surfaces and {111} plane surfaces when exposed to an anisotropic etchant.

In some embodiments, the etching process is controlled to where a ratio of the etch rate in the {100} plane to the etch rate in the {111} plane is between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN₄OH), hydrazine (N₂H₄), or tetra methyl ammonium hydroxide (TMAH). The actual etch rates of the silicon substrate depend on the concentration of the etchant in the aqueous solution, the temperature of the aqueous solution, and a concentration of the dopant in the substrate (if any). Typically, the mask layer is formed of a material that is selective to anisotropic etch compared to the underlying monocrystalline silicon substrate. Examples of suitable mask materials include silicon oxide (SiₓO_{y}) or silicon nitride (SiₓN_{y}). In some embodiments, the mask layer has a thickness of about 100 nm or less, such as about 50 nm or less, or about 30 nm or less. The mask layer may be patterned using any suitable combination of lithography and material etching patterning methods.

The second substrate may include a bulk material, and a plurality of material layers disposed on the bulk material. The bulk material may include any semiconductor material suitable for manufacturing semiconductor devices, such as silicon, silicon carbide, silicon germanium, germanium, group III-V semiconductor materials, group II-VI semiconductor materials, or combinations thereof. While some high-performance processors like CPUs, GPUS, neural processing units (NPUs), and tensor processing units (TPUs) are typically made out of silicon, some other high power density (hence substantial heat-generating) devices may comprise silicon carbide or gallium nitride, for example. In some embodiments, the second substrate may include a monocrystalline wafer, such as a silicon wafer, a plurality of device components formed in or on the silicon wafer, and a plurality of interconnect layers formed over the plurality of device components. In other embodiments, the second substrate may comprise a reconstituted substrate, e.g., a substrate formed from a plurality of singulated devices embedded in a support material. In some embodiments, each semiconductor device may have its own individual cold plate fabricated through a reconstitution process.

The bulk material of the second substrate may be thinned after the semiconductor device 204 is formed using one or more backgrinding, etching, and polishing operations that remove material from the backside. Thinning the second substrate may include using a combination of grinding and etching processes to reduce the thickness (in the Z-direction) to about 450 μm or less, such as about 200 μm or less, or about 150 μm or less or about 50 μm or less. After thinning, the backside 220 may be polished to a desired smoothness using a chemical mechanical polishing (CMP) process, and the dielectric material layer may be deposited thereon. In some embodiments, the dielectric material layer may be polished to a desired smoothness to prepare the second substrate for the bonding process. In some embodiments, the method 70 includes forming a plurality of metal features in the dielectric material layer in preparation for a hybrid bonding process, such as by use of a damascene process.

In some embodiments, the active side of the second substrate is temporarily bonded to a carrier substrate (not shown) before the thinning process. When used, the carrier substrate provides support for the thinning operation and/or for the thinned material to facilitate substrate handling during one or more of the subsequent manufacturing operations described herein.

Here, the method 70 may include forming dielectric layers on one or both the first and second substrates, and directly bonding includes forming dielectric bonds between a first dielectric material layer of the first substrate and a second dielectric material layer of the second substrate (or forming direct dielectric bonds between one substrate (which may have a native oxide layer at its bonding surface) and a dielectric material layer of the other substrate). Direct bonding processes join dielectric layers by forming strong chemical bonds (e.g., covalent bonds) between the dielectric layers.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces (e.g., a “very slight etch” using plasma or wet chemical treatment as taught in U.S. Pat. No. 6,902,987) to weaken or open chemical bonds in the dielectric material, and terminating the surfaces with a desired species (e.g., also as described in U.S. Pat. No. 6,902,987). Smoothing the surfaces may include polishing the first and second substrates using a CMP process. Simultaneously activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, in some embodiments that utilize a nitrogen plasma for activation that terminates the bonding surface with a nitrogen-containing species, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. Such an oxygen concentration peak will be more detectable when the bonding layers do not contain oxygen, such as layers containing silicon nitride or silicon carbon nitride.

In some embodiments, the plasma is formed using a nitrogen-containing gas, e.g., N₂, and the terminating species includes nitrogen, or nitrogen and hydrogen. In some embodiments, fluorine may also be present within the plasma. In some embodiments, the surfaces may be activated using a wet cleaning or etching process, e.g., by exposing the surfaces to an aqueous ammonia solution (e.g., ammonium hydroxide). In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between the first and second substrates at block 72 may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH₂ groups), it is believed that a chemical bond is formed in part from the nitrogen species, wherein hydrogen gas byproducts (H₂ gas) of the chemical reaction diffuse away from the interfacial bonding surfaces. In some embodiments, the direct bond is strengthened using an anneal process, where the substrates are heated to and maintained at a temperature of greater than about 30° C. and less than about 450° C., for example, greater than about 50° C. and less than about 250° C., or about 150° C., for a duration of about 5 minutes or more, such as about 15 minutes. Typically, the bonds will strengthen over time even without the application of heat. Thus, in some embodiments, the method does not include heating the substrates.

In embodiments where the first and second substrates are bonded using hybrid dielectric and metal bonds, the method 70 may further include planarizing or recessing the metal features below the dielectric field surface before contacting and bonding the dielectric material layers. After the dielectric bonds are formed, the first and second substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia Holding Corp., San Jose, CA, USA.

At block 74, the method 70 includes singulating at least one integrated cooling assembly 203 from the bonded first and second substrates. Singulation after bonding may impart distinctive structural characteristics on the integrated cooling assembly 203 as the cold plate 206 has the same perimeter as the semiconductor device 204 bonded thereto. Thus, the sidewalls (e.g., side surfaces) of the cold plate 206 are typically flush with the sidewalls (e.g., side surfaces) of the semiconductor device 204 about their common perimeters. In some embodiments, the cold plate 206 is singulated from the first substrate using a process that cuts or divides the first substrate in a vertical plane, i.e., in the Z-direction. In those embodiments, the side surfaces of the cold plate 206 are substantially perpendicular to the backside 220 of the semiconductor device 204, i.e., a horizontal (X-Y) plane of an attachment interface between the semiconductor device 204 and the cold plate 206. In some embodiments, the cold plate 206 is singulated using a saw or laser dicing process.

At block 76, the method 70 may include connecting the integrated cooling assembly 203 to the package substrate 202 and sealing a package cover 208 comprising inlet and outlet openings 212 to the integrated cooling assembly 203 by use of a sealing material layer 222, such as a molding compound that is cured.

At block 78, the method 70 may include, before or after sealing the package cover 208 to the integrated cooling assembly 203, forming inlet and outlet openings 222A in the sealing material layer 222 to fluidly connect the inlet and outlet openings 212 of the package cover 208 to the cold plate 206.

FIG. 7B shows a method 80 that can be used to manufacture example stacked semiconductor devices described herein. The method 80 may be used to manufacture the stacked semiconductor device 800 as shown in FIGS. 8A-8B.

At block 81, the method 80 includes providing a first semiconductor device. The method 80 may comprise forming a first semiconductor device. The first semiconductor device may be the first semiconductor device 810 as described in relation to FIGS. 8A-8C.

At block 82, the method 80 includes providing a second semiconductor device comprising one or more circuits to deliver power. The method may comprise forming a second semiconductor device. The second semiconductor device may be the second semiconductor device 820 as described in relation to FIGS. 8A-8B, or the second semiconductor device 850 as described in relation to FIG. 8C.

At block 83, the method 80 includes attaching the second semiconductor device to the backside of the first semiconductor device. The attaching may comprise directly bonding or directly hybrid bonding the first semiconductor device to the second semiconductor device. In some embodiments, the attaching may be performed using any suitable technique (e.g., soldering, adhesive, etc.).

FIG. 7C shows a method 85 that can be used to manufacture example integrated cooling assemblies described herein. The method 85 may be used to manufacture integrated cooling assemblies comprising stacked semiconductor devices (e.g., stacked semiconductor device 800 as shown in FIG. 8B, assembly 840 as shown in FIG. 8C, stacked semiconductor devices as shown in FIGS. 9C-9E).

At block 86, the method 85 includes providing a first substrate comprising a cold plate. Providing the first substrate may include forming the cold plate. The cold plate may be any suitable cold plate, such as those shown in various embodiments of the present disclosure. The cold plate may be any suitable cold plate, such as those mentioned throughout the present disclosure (e.g., cold plate 206, cold plate 506, cold plate 606, cold plate 830, cold plate comprising a second semiconductor device 850, cold plate comprising apparatus 930, cold plate comprising apparatus 940, cold plate comprising apparatus 950, etc.). In some embodiments, the cold plate comprises semiconductor material. The cold plate may be formed of any suitable material (e.g., semiconductor material, spacer material, etc.).

In some embodiments, a cold plate may comprise a material layer, such as cold plate 206 of FIGS. 3-4, cold plate 506 of FIG. 5, or cold plate 606 of FIG. 6A. Forming the cold plate may comprise etching or patterning channels in a material layer (e.g., semiconductor material layer). The cold plate may comprise a material layer with vias, such as cold plate 830 of FIG. 8B. Forming the cold plate may comprise etching or patterning channels between vias in a material layer. The etching or patterning of channels may be done after or before vias are formed in a material layer. In some embodiments, a cold plate may comprise vias and active devices in a material layer, such as second semiconductor device 850 of FIG. 8C. Forming the cold plate may comprise forming channels in a material layer before or after forming active devices in a material layer.

In some embodiments, a cold plate may comprise an apparatus. In some embodiments, a cold plate may comprise active devices and spacer material, such as the cold plate may be the apparatus 930 of FIG. 9C or apparatus 940 of FIG. 9D. Forming the cold plate may comprise stacking and attaching active devices and spacer layers to form channels. Forming the cold plate may comprise stacking and attaching active devices embedded in spacer material, and forming channels in the spacer material such as the apparatus 950 of FIG. 9E.

At block 87, the method 85 includes providing a second substrate comprising a semiconductor device. The method may comprise forming a semiconductor device. In some embodiments, the semiconductor device may be a first semiconductor device (e.g., the first semiconductor device 810 as described in relation to FIGS. 8A-8B). In some embodiments, the second substrate may comprise a stacked semiconductor device (e.g., stacked semiconductor device 800 of FIGS. 8A-8B).

At block 88, the method 85 includes attaching the first substrate to the second substrate. The attaching may comprise directly bonding or directly hybrid bonding the first substrate to the second substrate. In some embodiments, the attaching may be performed using any suitable technique (e.g., soldering, adhesive, etc.). In some embodiments, the method 85 may include attaching the first substrate comprising a cold plate to a stacked semiconductor device (e.g., attaching cold plate 830 to a stacked semiconductor device 800 as shown in FIG. 8B). In some embodiments, the method 85 may include attaching a cold plate comprising a second semiconductor device to a first semiconductor device (e.g., attaching second semiconductor device 850 to a first semiconductor device 810 as shown in FIG. 8C). In some embodiments, the method 85 may include attaching a cold plate comprising an apparatus to a first semiconductor device (e.g., attaching apparatus 930, apparatus 940, apparatus 950, to first semiconductor device 810 as shown in FIG. 9C-9E). In some embodiments, the method may further comprise attaching a cover (e.g., cover plate 939 of FIG. 9C) to the second substrate (e.g., the cold plate 830 of FIG. 8B, the second semiconductor device 850 of FIG. 8C, apparatus 930 of FIG. 9C, apparatus 950 of FIG. 9E, or any suitable second substrate or apparatus).

FIG. 7D shows a method 90 that can be used to manufacture example stacked semiconductor devices described herein. The stacked semiconductor devices may be stacked semiconductor devices as shown in FIGS. 9B-9E.

At block 91, the method 90 includes providing a first semiconductor device. The method 90 may comprise forming a first semiconductor device. The first semiconductor device may be the first semiconductor device 810 as described in relation to FIGS. 9B-9E.

At block 92, the method 90 includes providing an apparatus comprising a plurality of second semiconductor devices. The method 90 may comprise forming an apparatus as described in relation to FIGS. 9A-9E. The apparatus may be the apparatus 920 as shown in FIGS. 9A-9B, the apparatus 930 as shown in FIG. 9C, the apparatus 940 as shown in FIG. 9D, or the apparatus 950 as shown in FIG. 9E.

At block 93, the method 90 includes attaching an edge of the apparatus to a backside of the first semiconductor device. The attaching may comprise directly bonding or directly hybrid bonding the edge of the apparatus to the backside of the first semiconductor device. In some embodiments, the attaching may be performed using any suitable technique (e.g., soldering, adhesive, etc.).

FIG. 8A shows a stacked semiconductor device 800 comprising a first semiconductor device 810 (e.g., chip) attached to a second semiconductor device 820 (e.g., an active power delivery chip), according to some embodiments. In some embodiments, the stacked semiconductor device 800 can be used in place of the semiconductor device 204 as shown in FIGS. 2C, 3, and 4, the semiconductor device 604 as shown in FIGS. 6A-6B, or any suitable semiconductor device such as those described in embodiments of the present disclosure. Advantageously, moving the active power delivery components from a first semiconductor device 810 to a second semiconductor device 820 and attaching the second semiconductor device 820 to a backside of a first semiconductor device 810 can reduce the size of the first semiconductor device 810 (e.g., remove about 5% to about 10% of the chip real estate or volume). The active power may be up to or about 10% of the chip power.

The first semiconductor device 810 may comprise different devices, circuits, or circuit blocks. A bottom surface 801 of the first semiconductor device 810 may be referred to as a frontside of the first semiconductor device 810, and a top surface 811 of the first semiconductor device 810 may be referred to as a backside of the first semiconductor device 810. The first semiconductor device 810 may comprise a back portion 813 (e.g., top portion) and a front portion 816 (e.g., bottom portion). The back portion 813 may comprise semiconductor material 812 (e.g., silicon) and one or more TSVs or vias 814 (e.g., vertical interconnects). The front portion 816 of the first semiconductor device 810 may comprise semiconductor material, one or more TSVs or vias, one or more components, and a redistribution layer (e.g., interconnect layer). The semiconductor material in a front portion 816 may be similar to or the same as semiconductor material 812 in a back portion 813. The TSVs or vias in a front portion 816 may be similar or the same as vias 814 in a back portion 813. The components may include active and/or passive components. One or more components in the front portion 816 may be active power delivery components or active power delivery circuits such as power regulators to provide power to other components in the front portion 816. The front portion 816 may or may not comprise a redistribution layer. The redistribution layer may be at a bottom portion of the first semiconductor device 810 (e.g., frontside of the chip or the second semiconductor device 810) and may comprise a dielectric layer (e.g., any suitable dielectric layer, such as those mentioned in the present disclosure) and interconnects disposed in the dielectric layer. The interconnects may connect different devices, circuits, or circuit blocks in the first semiconductor device 810.

The second semiconductor device 820 can have one or more active circuits such as power regulators, voltage dividers, DC-DC converters, or any suitable active circuits such as those mentioned in the present disclosure. A bottom surface of the second semiconductor device 820 may be referred to as a frontside or frontside surface 821 of the second semiconductor device 820, and a top surface of the second semiconductor device 820 may be referred to as a backside or backside surface 829 of the second semiconductor device 820. In some embodiments, a backside or backside surface (e.g., top surface 811) of the first semiconductor device 810 is directly bonded or hybrid bonded to a frontside or frontside surface 821 of the second semiconductor device 820. In some embodiments, the one or more active circuits may be integrated on a single substrate (e.g., an IC, as shown as second semiconductor device 820 in FIG. 8A). In other embodiments, the one or more active circuits may be separately packaged and attached to each other.

The second semiconductor device 820 may comprise a back portion 823 (e.g., top portion) and a front portion 826 (e.g., bottom portion). The back portion 823 may comprise a semiconductor material 822 (e.g., silicon) and one or more TSVs or vias 824 (e.g., vertical interconnects). The front portion 826 of the second semiconductor device 820 may comprise semiconductor material, one or more TSVs or vias, one or more components, and a redistribution layer (e.g., interconnect layer). The semiconductor material in a front portion 826 may be similar to or the same as semiconductor material 822 in a back portion 823. The TSVs or vias in a front portion 826 may be similar or the same as vias 824 in a back portion 823. The one or more components in a front portion 826 may include active and/or passive components. The front portion 826 may include one or more components that are active power delivery components or active power delivery circuits such as power regulators to provide power to other components in the front portion 816 of the first semiconductor device 810. In some embodiments, there may not be active power delivery components in the front portion 816, and one or more active power delivery components in the front portion 826 provide power or drive one or more components in the front portion 816. In some embodiments, there may be some (e.g., one or more) active power delivery components in the front portion 826 and some (e.g., one or more) active power delivery components in the front portion 816 for providing power to or driving components in the front portion 816. One or more first active power delivery components or circuits in a front portion 816 and one or more second active power delivery components or circuits in a front portion 826 may drive one or more components in the front portion 816. The one or more first circuits to deliver power may be first power regulators, and the one or more second circuits to deliver power may be second power regulators. The front portion 826 may or may not include a redistribution layer. The redistribution layer may be at a bottom portion of the second semiconductor device 820 (e.g., frontside of the chip or second semiconductor device 820) and comprise a dielectric layer (e.g., any suitable dielectric layer, such as those mentioned in the present disclosure) and interconnects disposed in the dielectric layer. For example, interconnects of a redistribution layer may distribute a voltage from a via 824 of the second semiconductor device 820 to one or more vias (e.g., shown as groups of three vias 814) of the first semiconductor device 810. Although a group of three vias 814 is shown in FIG. 8A, any suitable number of vias 814 may be used (e.g., one, two, three or more, etc.). A voltage from the second semiconductor device 820 may be connected to a via 814 in the first semiconductor device 810 through the redistribution layer attached to the top surface 811 (e.g., backside) of the first semiconductor device 810. For example, a voltage (e.g., 2V) from a TSV or via 824 of the second semiconductor device 820 may be connected to three vias 814 of the first semiconductor device 810 via the redistribution layer, and distributed through the redistribution layer to a substrate below the first semiconductor device 810. In some embodiments, the first semiconductor device 810 may have pins, microbumps, etc., and may connect to a socket or substrate with I/O connections.

In some embodiments, the first semiconductor device 810 may comprise redistribution layers at a top and/or bottom portion of the first semiconductor device 810 (e.g., backside and frontside of the chip). In some embodiments, first semiconductor device 810 may further comprise a redistribution layer on a top surface 811 of first semiconductor device 810 (e.g., redistribution layer is a part of first semiconductor device 810, or another redistribution layer that is different redistribution layer is a part of first semiconductor device 810).

FIG. 8B shows a cold plate 830 attached to a semiconductor device 800, according to some embodiments. In some embodiments, the cold plate 830 may be used in place of the cold plate 206 of FIGS. 2C, 3, and 4, the cold plate 606 of FIGS. 6A-6B, or any suitable cold plate such as those mentioned in embodiments of the present disclosure. The cold plate 830 may comprise TSVs or vias 834 and one or more channels (e.g., channels 836, 838) embedded in a semiconductor material 832 (e.g., silicon). The TSVs or vias 834 may be disposed between channels 836, 838.

In some embodiments, the cold plate 830 may comprise one or more channels (e.g., shown as four channels 836 in FIG. 8B) facing down (e.g., towards the second semiconductor device 820). Although four channels 836 are shown in FIG. 8B, any suitable number of channels 836 may be used in a cold plate 830 (e.g., one, two, three, four or more, etc.). The channel 836 may be defined by a portion of a backside surface 829 of the second semiconductor device 820. A portion of the backside surface 829 of the second semiconductor device 820 may be in direct contact with coolant fluid from a coolant channel 836.

In some embodiments, the cold plate may comprise one or more channels 838 (e.g., shown as one channel 838 in FIG. 8B) facing up (e.g., away from the second semiconductor device 820). For example, a substrate or a cover (e.g., similar to cover plate 939 shown in zoomed in box of FIG. 9C) may be attached to the top of the second semiconductor device 820, with portions of the substrate or cover to define the channel 838. Although only one channel 838 is shown in FIG. 8B, any suitable number of channels 838 may be used in cold plate 830 (e.g., two, three, four or more, etc.) Although FIG. 8B shows a cold plate 830 with a mix of channels 836 and 838, in some embodiments only one type of channel may be used (e.g., only channels 836 are used, the channel 838 is replaced with channel 836 in FIG. 8B, or each channel 836 is replaced with a channel 838 in FIG. 8B).

FIG. 8C shows an assembly 840 comprising a second semiconductor device 850 (e.g., active power delivery and cooling system in one chip) with an integrated cold plate attached to a first semiconductor device 810, according to some embodiments. In some embodiments, the assembly 840 may be used in place of the cold plate 206 and the semiconductor device 204 of FIGS. 2C, 3, and 4, the cold plate 606 and the semiconductor device 604, or any suitable combination of a cold plate and semiconductor device such as those described in the present disclosure. The second semiconductor device 850 of FIG. 8C may be similar to or the same as the second semiconductor device 820 of FIGS. 8A-8B, except that second semiconductor device 850 further comprises coolant channels 858. For example, the semiconductor material 852, the TSVs or vias 854, and front portion 856 of second semiconductor device 850 may be the same as or similar to the semiconductor material 822, the TSVs or vias 824, and the front portion 826 of second semiconductor device 820. The TSVs or vias 854 may be disposed between coolant channels 858. A bottom surface of the second semiconductor device 850 may be referred to as a frontside or frontside surface 851 of the second semiconductor device 850. In some embodiments, a backside or backside surface (e.g., top surface 811) of the first semiconductor device 810 is directly bonded or hybrid bonded to a frontside or frontside surface 851 (e.g., bottom surface) of the second semiconductor device 850. The second semiconductor device 850 may comprise a bottom portion and a top portion. A bottom portion of the second semiconductor device 850 may be similar to or the same as second semiconductor device 820. The top portion of the second semiconductor device 850 may comprise one or more coolant channels 858 disposed in the semiconductor material 852. The one or more coolant channels 858 may face up (e.g., away from the first semiconductor device 810). For example, a substrate or a cover (e.g., similar to cover plate 939 shown in zoomed in box of FIG. 9C) may be attached to the top of the second semiconductor device 850, with portions of the substrate or cover to define the channel 858.

FIG. 9A shows forming an apparatus 920 of second semiconductor devices 921 (e.g., an active power delivery chip stack). A method may include providing a plurality of semiconductor devices 921 (e.g., active power delivery chips, shown as six chips in FIG. 9A). Although FIG. 9A and various other figures in the present disclosure (e.g., FIGS. 9B-9E) may show six semiconductor devices 921 or chips, the apparatus (e.g., apparatus 920, 930, 940, 950) may include any suitable number of devices or chips (e.g., 1, 2, 3, 4, 5, 7 or more, etc.). In some embodiments, at least one second semiconductor device of the second semiconductor devices 921 may comprise one or more active power delivery components or circuits. For example, any suitable number (e.g., 1, 2, 3 or more, etc.) of second semiconductor devices or chips (e.g., some or a first portion of the second semiconductor devices 921) may include one or more active power delivery components, and any suitable number (e.g., 1, 2, 3 or more, etc.) of second semiconductor devices or chips (e.g., some or a remaining portion of the second semiconductor devices 921) may not include active power delivery components. In some embodiments, each second semiconductor device of the second semiconductor devices 921 may comprise one or more active power delivery components. Each semiconductor device 921 (e.g., active power delivery chip) may comprise same or different active power delivery circuit. Each semiconductor device 921 may comprise a front portion 926 and a back portion (e.g., similar to or the same as a front portion 826 and back portion of the second semiconductor device 820 as described in relation to FIG. 8A-8C). A front portion 926 of a second semiconductor device may include one or more active power delivery components or circuits. In some embodiments, one or more of the second semiconductor devices 921 in the plurality of second semiconductor devices may not include one or more active power delivery components, and a front portion 926 of the second semiconductor device 921 may not include one or more active power delivery components. In some embodiments, the back portion may or may not include vias or TSVs. In some embodiments, a power regulator from a front portion of a semiconductor device 921 may provide power to or drive a component in the front portion 816 of the first semiconductor device 810.

The front portion 926 of the semiconductor device 921 may or may not include a redistribution layer. The redistribution layer may be in a front portion 926 of the semiconductor device 921 (e.g., frontside of the chip or second semiconductor device 921). The redistribution layer may comprise a dielectric layer and a first interconnect 922 and a second interconnect 924 disposed in the dielectric layer. The dielectric layer may comprise any suitable dielectric material, such as those mentioned in the present disclosure. A method may include stacking and bonding the semiconductor devices 921 to form the apparatus 920 of second semiconductor devices 921. The plurality of semiconductor devices 921 may be directly bonded or directly hybrid bonded together. In some embodiments, the semiconductor devices 921 may be attached to each other using any suitable technique (e.g., soldering, adhesive, etc.). In some embodiments, an edge 928 of the apparatus 920 of second semiconductor devices 921 may be polished to a desired smoothness using a chemical mechanical polishing (CMP) process to prepare a surface of the apparatus 920 of second semiconductor devices 921 for a bonding process to the first semiconductor device 810. In some embodiments, the edge of the apparatus 920 of second semiconductor devices 921 may be prepared for bonding using any suitable techniques, such as those mentioned in relation to FIGS. 10A-10B.

FIG. 9B shows the apparatus 920 comprising second semiconductor devices 921 bonded to the first semiconductor device 810. The apparatus 920 may be attached to a backside of the first semiconductor device 810, and an edge of each second semiconductor device 921 may face a backside of the first semiconductor device 810. An edge surface of the apparatus 920 may be attached to a back or a backside of the first semiconductor device 810. In some embodiments, the apparatus 920 may be directly bonded or hybrid bonded to a backside of the first semiconductor device 810. A power or voltage (e.g., 2V) may be applied at a top of a first interconnect 922, the power may be applied to a circuit of the semiconductor device 921 (e.g., reduce noise of 2V, convert 2V to 1.2V such as downconverter, etc.) the output will be propagated through the second interconnect 924, to go to first semiconductor device 810. In some embodiments, at least one second semiconductor device 921 comprises one or more circuits to deliver power. The at least one second semiconductor device 921 may drive the first semiconductor device 820. In some embodiments, the first semiconductor device 820 comprises one or more first circuits to deliver power, and at least one second semiconductor device 921 comprises one or more second circuits to deliver power. The one or more first circuits to deliver power and the one or more second circuits to deliver power may drive one or more components in a front portion 816 of the first semiconductor device 810. The one or more first circuits to deliver power may be first power regulators, and the one or more second circuits to deliver power may be second power regulators.

FIG. 9C shows an apparatus 930 bonded to first semiconductor device 810. The apparatus 930 comprises second semiconductor devices 931 (e.g., active power delivery chips) and spacers (e.g., spacers 932 and spacer 934) disposed between second semiconductor devices 931. In some embodiments, the second semiconductor devices 931 may be similar to or the same as second semiconductor devices 921. A method may include attaching or bonding the second semiconductor devices 931 and spacers (e.g., spacers 932 and spacer 934) to form the apparatus 930. In some embodiments, the second semiconductor devices 931 and spacers (e.g., spacers 932 and spacer 934) may be attached to each other using any suitable techniques (e.g., bonding, direct bonding, hybrid bonding, solder, adhesive, etc.). The method may further include attaching or bonding the apparatus 930 to the first semiconductor device 810. The apparatus 930 may be attached to a backside of the first semiconductor device 810, and an edge of each second semiconductor device 931 may face a backside of the first semiconductor device 810. An edge surface of the apparatus 930 (e.g., edge surfaces of the second semiconductor devices 931, edge surface of a spacer 934 as shown in FIG. 9C) may be attached to a back or a backside of the first semiconductor device 810. In some embodiments, an edge of the apparatus 930 may be polished to a desired smoothness using a chemical mechanical polishing (CMP) process to prepare a surface of the apparatus 930 for a bonding process to the first semiconductor device 810. In some embodiments, the edge of the apparatus 930 may be prepared for bonding using any suitable techniques, such as those mentioned in relation to FIGS. 10A-10B. In some embodiments, the apparatus 930 may be directly bonded or hybrid bonded to a backside of the first semiconductor device 810. A spacer (e.g., spacers 932 and spacer 934) may comprise silicon or other material (e.g., a material that may not cause thermal mismatch with other materials in structure). The apparatus 930 may include one or more channels (e.g., channels 936 or channel 938). For example, the apparatus 930 may include one or more channels 936 that are facing down (e.g., towards the first semiconductor device 810). A top surface (e.g., backside of first semiconductor device 810) may define a channel 936 along with portions of surfaces of second semiconductor devices 931, and a side surface of spacer 932. The apparatus 930 may include one or more channels 938 that are facing up (e.g., away from the first semiconductor device 810). In some embodiments, a substrate or cover (e.g., cover plate 939, shown in a zoomed-in box of FIG. 9C) may define a channel 938 along with a side surface of a spacer 934, and portions of surfaces of second semiconductor devices 931. The apparatus 930 may be used to cool the first semiconductor device 810 and the second semiconductor devices 931. Although FIG. 9C show four channels 936 facing the first semiconductor device 810, and one channel 938 facing away from first semiconductor device 810, the apparatus 930 may include any suitable number of channels (e.g., 1, 2, 3 or more, etc.) in any suitable arrangement (e.g., all face down, all face up, mix of channels facing up and facing down).

FIG. 9D shows an apparatus 940 bonded to a first semiconductor device 810. The apparatus 940 comprises second semiconductor devices 941 (e.g., active power delivery chips) and spacers 942 disposed between second semiconductor device 941. In some embodiments, the second semiconductor devices 941 may be similar to or the same as second semiconductor devices 921 and 931. The spacers 942 may be similar to spacers 932, but may be taller. The apparatus 940 may include spacers 942 on outside edges of second semiconductor devices 941. A method may include attaching or bonding the second semiconductor devices 941 and spacers 942 to form the apparatus 940. In some embodiments, the second semiconductor devices 941 and spacers 942 may be attached to each other using any suitable techniques (e.g., bonding, direct bonding, hybrid bonding, solder, adhesive, etc.). The method may further include attaching or bonding the apparatus 940 to the first semiconductor device 810. The apparatus 940 may be attached to a backside of the first semiconductor device 810, and an edge of each second semiconductor device 941 may face a backside of the first semiconductor device 810. An edge surface of the apparatus 940 (e.g., edge surfaces of the spacers 942 and second interconnects 924 as shown in FIG. 9D) may be attached to a back or a backside of the first semiconductor device 810. In some embodiments, an edge of the apparatus 940 may be polished to a desired smoothness using a chemical mechanical polishing (CMP) process to prepare a surface of the apparatus 940 for a bonding process to the first semiconductor device 810. In some embodiments, the edge of the apparatus 940 may be prepared for bonding using any suitable techniques, such as those mentioned in relation to FIGS. 10A-10B. In some embodiments, the apparatus 940 may be directly bonded or hybrid bonded to a backside of the first semiconductor device 810. A spacer 942 may comprise silicon or other material (e.g., a material that may not cause thermal mismatch with other materials in structure). The apparatus 940 may include one or more channels 946. For example, the apparatus 940 may include one or more channels 946 that are facing down (e.g., towards the first semiconductor device 810). A top surface (e.g., backside of first semiconductor device 810) may define a channel 946 along with portions of surfaces of second semiconductor devices 941, and a side surface of spacer 942. The apparatus 940 may be used to cool the first semiconductor device 810 along with the second semiconductor devices 941. Although FIG. 9D show six channels 946 facing the first semiconductor device 810, the apparatus 940 may include any suitable number of channels (e.g., 1, 2, 3 or more, etc.) in any suitable arrangement (e.g., all face down, all face up, mix of channels facing up and facing down).

FIG. 9E shows an apparatus 950 bonded to a first semiconductor device 810. The apparatus 950 comprises second semiconductor devices 951 (e.g., active power delivery chips) embedded in spacers 952. In some embodiments, the second semiconductor devices 951 may be similar to or the same as second semiconductor devices 921, 931, and 941. A method may include etching a first opening in a spacer 952 and attaching a second semiconductor devices 951 into the first opening of the spacer 952. The method may include etching a second opening in a spacer 952 to form a channel 956 or a channel 958. A method may include attaching or bonding the second semiconductor devices 951 to spacers 952 to form the apparatus 950. In some embodiments, the second semiconductor devices 951 and spacers 952 may be attached to each other using any suitable techniques (e.g., bonding, direct bonding, hybrid bonding, solder, adhesive, etc.). The method may further include attaching or bonding the apparatus 950 to the first semiconductor device 810. The apparatus 950 may be attached to a backside of the first semiconductor device 810, and an edge of each second semiconductor device 951 may face a backside of the first semiconductor device 810. An edge surface of the apparatus 950 (e.g., edge surfaces of the spacers 952, of portions of spacer 952 adjacent to an opening in spacer 952, of second interconnects 924 as shown in FIG. 9E) may be attached to a back or a backside of the first semiconductor device 810. In some embodiments, an edge of the apparatus 950 may be polished to a desired smoothness using a chemical mechanical polishing (CMP) process to prepare a surface of the apparatus 950 for a bonding process to the first semiconductor device 810. In some embodiments, the edge of the apparatus 950 may be prepared for bonding using any suitable techniques, such as those mentioned in relation to FIGS. 10A-10B. In some embodiments, the apparatus 950 may be directly bonded or hybrid bonded to a backside of the first semiconductor device 810. A spacer 952 may comprise silicon or other material (e.g., a material that may not cause thermal mismatch with other materials in structure). The apparatus 950 may include one or more channels 956. For example, the apparatus 950 may include one or more channels 956 that are facing down (e.g., towards the first semiconductor device 810). A top surface (e.g., backside of first semiconductor device 810) may define a channel 956 along with portions of the spacer 952. The apparatus 950 may include one or more channels 958 that are facing up (e.g., away from the first semiconductor device 810). In some embodiments, a substrate or cover (e.g., similar to cover plate 939 shown in zoomed in box of FIG. 9C) may define a channel 958 along with portions of a spacer 952. The apparatus 950 may be used to cool the first semiconductor device 810 and the second semiconductor devices 951. Although FIG. 9E shows a channel 956 facing down and a channel 958 facing up, the apparatus 950 may include any suitable number of channels (e.g., 1, 2, 3 or more, etc.) in any suitable arrangement (e.g., all face down, all face up, mix of channels facing up and facing down).

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 1008a and/or 1008b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Patent Application Publication No. 20250006679, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 10A and 10B schematically illustrate cross-sectional side views of first and second elements 1002, 1004 prior to and after, respectively, a process for forming a directly bonded structure, and more particularly a hybrid bonded structure, according to some embodiments. In FIG. 10B, a bonded structure 1000 comprises the first and second elements 1002 and 1004 that are directly bonded to one another at a bond interface 1018 without an intervening adhesive. Conductive features 1006a of a first element 1002 may be electrically connected to corresponding conductive features 1006b of a second element 1004. In the illustrated hybrid bonded structure 1000, the conductive features 1006a are directly bonded to the corresponding conductive features 1006b without intervening solder or conductive adhesive.

The conductive features 1006a and 1006b of the illustrated embodiment are embedded in, and can be considered part of, a first bonding layer 1008a of the first element 1002 and a second bonding layer 1008b of the second element 1004, respectively. Field regions of the bonding layers 1008a, 1008b extend between and partially or fully surround the conductive features 1006a, 1006b. The bonding layers 1008a, 1008b can comprise layers of non-conductive materials suitable for direct bonding, as described above, and the field regions are directly bonded to one another without an adhesive. The non-conductive bonding layers 1008a, 1008b can be disposed on respective front sides 1014a, 1014b of base substrate portions 1010a, 1010b.

The first and second elements 1002, 1004 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 1002, 1004, and back-end-of-line (BEOL) interconnect layers over such semiconductor portions. The bonding layers 1008a, 1008b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1010a, 1010b, and can electrically communicate with at least some of the conductive features 1006a, 1006b. Active devices and/or circuitry can be disposed at or near the front sides 1014a, 1014b of the base substrate portions 1010a, 1010b, and/or at or near opposite backsides 1016a, 1016b of the base substrate portions 1010a, 1010b. In other embodiments, the base substrate portions 1010a, 1010b may not include active circuitry, but may instead comprise dummy substrates, passive interposers, passive optical elements (e.g., glass substrates, gratings, lenses), etc. The bonding layers 1008a, 1008b are shown as being provided on the front sides of the elements, but similar bonding layers can be additionally or alternatively provided on the back sides of the elements.

In some embodiments, the base substrate portions 1010a, 1010b can have significantly different coefficients of thermal expansion (CTEs), and bonding elements that include such different based substrate portions can form a heterogenous bonded structure. The CTE difference between the base substrate portions 1010a and 1010b, and particularly between bulk semiconductor (typically single crystal) portions of the base substrate portions 1010a, 1010b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 1010a, 1010b comprises a more conventional substrate material. For example, one of the base substrate portions 1010a, 1010b comprises lithium tantalate (LiTaO₃) or lithium niobate (LiNbO₃), and the other one of the base substrate portions 1010a, 1010b comprises silicon (Si), quartz, fused silica glass, sapphire, or a glass. In other embodiments, one of the base substrate portions 1010a, 1010b comprises a III-V single semiconductor material, such as gallium arsenide (GaAs) or gallium nitride (GaN), and the other one of the base substrate portions 1010a, 1010b can comprise a non-III-V semiconductor material, such as silicon (Si), or can comprise other materials with similar CTE, such as quartz, fused silica glass, sapphire, or a glass. In still other embodiments, one of the base substrate portions 1010a, 1010b comprises a semiconductor material and the other of the base substrate portions 1010a, 1010b comprises a packaging material, such as a glass, organic or ceramic substrate.

In some arrangements, the first element 1002 can comprise a singulated element, such as a singulated integrated device die. In other arrangements, the first element 1002 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 1004 can comprise a singulated element, such as a singulated integrated device die. In other arrangements, the second element 1004 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 1002, 1004 are shown, any suitable number of elements can be stacked in the bonded structure 1000. For example, a third element (not shown) can be stacked on the second element 1004, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 1002. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1008a, 1008b, the bonding layers 1008a, 1008b can be prepared for direct bonding. Non-conductive bonding surfaces 1012a, 1012b at the upper or exterior surfaces of the bonding layers 1008a, 1008b can be prepared for direct bonding by polishing, for example, by chemical mechanical polishing (CMP). The roughness of the polished bonding surfaces 1012a, 1012b can be less than 30 Å rms. For example, the roughness of the bonding surfaces 1012a and 1012b can be in a range of about 0.1 Å rms to 15 Å rms, 0.5 Å rms to 10 Å rms, or 1 Å rms to 5 Å rms. Polishing can also be tuned to leave the conductive features 1006a, 1006b recessed relative to the field regions of the bonding layers 1008a, 1008b.

Preparation for direct bonding can also include cleaning and exposing one or both of the bonding surfaces 1012a, 1012b to a plasma and/or etchants to activate at least one of the surfaces 1012a, 1012b. In some embodiments, one or both of the surfaces 1012a, 1012b can be terminated with a species after activation or during activation (e.g., during the plasma and/or etch processes). Without being limited by theory, in some embodiments, the activation process can be performed to break chemical bonds at the bonding surface(s) 1012a, 1012b, and the termination process can provide additional chemical species at the bonding surface(s) 1012a, 1012b that alters the chemical bond and/or improves the bonding energy during direct bonding. In some embodiments, the activation and termination are provided in the same step, e.g., a plasma to activate and terminate the surface(s) 1012a, 1012b. In other embodiments, one or both of the bonding surfaces 1012a, 1012b can be terminated in a separate treatment to provide the additional species for direct bonding. In various embodiments, the terminating species can comprise nitrogen. For example, in some embodiments, the bonding surface(s) 1012a, 1012b can be exposed to a nitrogen-containing plasma. Other terminating species can be suitable for improving bonding energy, depending upon the materials of the bonding surfaces 1012a, 1012b. Further, in some embodiments, the bonding surface(s) 1012a, 1012b can be exposed to fluorine. For example, there may be one or multiple fluorine concentration peaks at or near a bond interface 1018 between the first and second elements 1002, 1004. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1000, the bond interface 1018 between two non-conductive materials (e.g., the bonding layers 1008a, 1008b) can comprise a very smooth interface with higher nitrogen (or other terminating species) content and/or fluorine concentration peaks at the bond interface 1018. In some embodiments, the nitrogen and/or fluorine concentration peaks may be detected using various types of inspection techniques, such as SIMS techniques. The polished bonding surfaces 1012a and 1012b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1008a and 1008b can be directly bonded to one another without an adhesive. In some embodiments, the elements 1002, 1004 are brought together at room temperature, without the need for application of a voltage, and without the need for application of external pressure or force beyond that used to initiate contact between the two elements 1002, 1004. Contact alone can cause direct bonding between the non-conductive surfaces of the bonding layers 1008a, 1008b (e.g., covalent dielectric bonding). Subsequent annealing of the bonded structure 1000 can cause the conductive features 1006a, 1006b to directly bond.

In some embodiments, prior to direct bonding, the conductive features 1006a, 1006b are recessed relative to the surrounding field regions, such that a total gap between opposing contacts after dielectric bonding and prior to anneal is less than 15 nm, or less than 10 nm. Because the recess depths for the conductive features 1006a and 1006b can vary across each element, due to process variation, the noted gap can represent a maximum or an average gap between corresponding conductive features 1006a, 1006b of two joined elements (prior to anneal). Upon annealing, the conductive features 1006a and 1006b can expand and contact one another to form a metal-to-metal direct bond.

During annealing, the conductive features 1006a, 1006b (e.g., metallic material) can expand while the direct bonds between surrounding non-conductive materials of the bonding layers 1008a, 1008b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 1006a, 1006b can comprise discrete pads, contacts, electrodes, or traces at least partially embedded in the non-conductive field regions of the bonding layers 1008a, 1008b. In some embodiments, the conductive features 1006a, 1006b can comprise exposed contact surfaces of TSVs (e.g., through silicon vias).

As noted above, in some embodiments, in the elements 1002, 1004 of FIG. 10A prior to direct bonding, portions of the respective conductive features 1006a and 1006b can be recessed below the non-conductive bonding surfaces 1012a and 1012b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1006a, 1006b or to average depths of the recesses relative to local non-conductive field regions. Even for an individual conductive feature 1006a, 1006b, the vertical recess can vary across the feature, and so can be measured at or near the lateral middle or center of the cavity in which a given conductive feature 1006a, 1006b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 1006a, 1006b across the direct bond interface 1018 (e.g., small or fine pitches for regular arrays).

In some embodiments, a pitch p of the conductive features 1006a, 1006b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 1006a and 1006b to one of the lateral dimensions (e.g., a diameter) of the bonding pad is less than is less than 20, or less than 10, or less than 5, or less than 3 and sometimes desirably less than 2. In various embodiments, the conductive features 1006a and 1006b and/or traces can comprise copper or copper alloys, although other metals may be suitable, such as nickel, aluminum, or alloys thereof. The conductive features disclosed herein, such as the conductive features 1006a and 1006b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1002, 1004, as shown, the orientations of one or more conductive features 1006a, 1006b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1006b in the bonding layer 1008b (and/or at least one internal conductive feature, such as a BEOL feature) of the upper element 1004 may be tapered or narrowed upwardly, away from the bonding surface 1012b. By way of contrast, at least one conductive feature 1006a in the bonding layer 1008a (and/or at least one internal conductive feature, such as a BEOL feature) of the lower element 1002 may be tapered or narrowed downwardly, away from the bonding surface 1012a. Similarly, any bonding layers (not shown) on the backsides 1016a, 1016b of the elements 1002, 1004 may taper or narrow away from the backsides, with an opposite taper orientation relative to front side conductive features 1006a, 1006b of the same element.

As described above, in an anneal phase of hybrid bonding, the conductive features 1006a, 1006b can expand and contact one another to form a metal-to-metal direct bond. In some embodiments, the materials of the conductive features 1006a, 1006b of opposite elements 1002, 1004 can interdiffuse during the annealing process. In some embodiments, metal grains grow into each other across the bond interface 1018. In some embodiments, the metal is or includes copper, which can have grains oriented along the 1011 crystal plane for improved copper diffusion across the bond interface 1018. In some embodiments, the conductive features 1006a and 1006b may include nanotwinned copper grain structure, which can aid in merging the conductive features during anneal. There is substantially no gap between the non-conductive bonding layers 1008a and 1008b at or near the bonded conductive features 1006a and 1006b. In some embodiments, a barrier layer may be provided under and/or laterally surrounding the conductive features 1006a and 1006b (e.g., which may include copper). In other embodiments, however, there may be no barrier layer under the conductive features 1006a and 1006b.

It is contemplated that any combination of the methods described above may be used to form the semiconductor devices or apparatuses, whether or not expressly recited herein.

The embodiments discussed above are intended to be illustrative and not limiting. One skilled in the art would appreciate that individual aspects of the cooling assemblies, device packages, stacked semiconductor devices, and methods discussed herein may be omitted, modified, combined, and/or rearranged without departing from the scope of the disclosure.

1. A stacked semiconductor device comprising:
a first semiconductor device having a backside; and
a second semiconductor device having a frontside and comprising one or more circuits to deliver power, wherein the backside of the first semiconductor device and the frontside of the second semiconductor device are directly bonded.

2. The stacked semiconductor device of claim 1, wherein:
the first semiconductor device is a chip; and
the second semiconductor device is an active power delivery chip, the active power delivery chip comprising at least one of: a power switch, a low-dropout regulator, a buck converter, a charge pump, a boost converter, a battery management circuit, a voltage monitor circuit, a current sensor, a dynamic voltage and frequency scaling circuit, or a battery protection circuit.

3. The stacked semiconductor device of claim 1, wherein the second semiconductor device drives the first semiconductor device.

4. The stacked semiconductor device of claim 1, wherein the backside of the first semiconductor device is hybrid bonded to the frontside of the second semiconductor device.

5. The stacked semiconductor device of claim 1, wherein:
a cold plate is attached to a backside of the second semiconductor device, the cold plate comprising a semiconductor material, a plurality of coolant channels, and at least one via; and
the at least one via is disposed between two coolant channels.

6. The stacked semiconductor device of claim 5, wherein the plurality of coolant channels face the second semiconductor device.

7. The stacked semiconductor device of claim 5, wherein the plurality of coolant channels face away from the second semiconductor device.

8. The stacked semiconductor device of claim 5, wherein:
at least one first coolant channel of the plurality of coolant channels faces the second semiconductor device; and
at least one second coolant channel of the plurality of coolant channels faces away from the second semiconductor device.

9. The stacked semiconductor device of claim 1, wherein:
the second semiconductor device further comprises a semiconductor material, a plurality of coolant channels facing away from the first semiconductor device, and at least one via; and
the at least one via is disposed between two coolant channels.

10. A stacked semiconductor device comprising:
a first semiconductor device having a backside; and
a second semiconductor device having a frontside and comprising one or more power regulators, wherein the backside of the first semiconductor device and the frontside of the second semiconductor device are directly bonded, wherein the one or more power regulators are in a front portion of the second semiconductor device and drives one or more components in a front portion of the first semiconductor device.

11. The stacked semiconductor device of claim 10, wherein the backside of the first semiconductor device is hybrid bonded to the frontside of the second semiconductor device.

12. The stacked semiconductor device of claim 10, wherein:
a cold plate is attached to a backside of the second semiconductor device, the cold plate comprising a semiconductor material, a plurality of coolant channels, and at least one via; and
the at least one via is disposed between two coolant channels.

13. The stacked semiconductor device of claim 12, wherein the plurality of coolant channels face the second semiconductor device.

14. The stacked semiconductor device of claim 12, wherein the plurality of coolant channels face away from the second semiconductor device.

15. The stacked semiconductor device of claim 12, wherein:
at least one first coolant channel of the plurality of coolant channels faces the second semiconductor device; and
at least one second coolant channel of the plurality of coolant channels faces away from the second semiconductor device.

16. The stacked semiconductor device of claim 10, wherein:
the second semiconductor device further comprises a semiconductor material, a plurality of coolant channels facing away from the first semiconductor device, and at least one via; and
the at least one via is disposed between two coolant channels.

17. A stacked semiconductor device comprising:
a first semiconductor device having a backside and comprising one or more first power regulators in a front portion of the first semiconductor device; and
a second semiconductor device having a frontside and comprising one or more second power regulators in a front portion of the second semiconductor device, wherein the backside of the first semiconductor device and the frontside of the second semiconductor device are directly bonded, and wherein the one or more first power regulators and the one or more second power regulators drive one or more components in the front portion of the first semiconductor device.

18. The stacked semiconductor device of claim 17, wherein the backside of the first semiconductor device is hybrid bonded to the frontside of the second semiconductor device.

19. The stacked semiconductor device of claim 17, wherein:
a cold plate is attached to a backside of the second semiconductor device, the cold plate comprising a semiconductor material, a plurality of coolant channels, and at least one via; and
the at least one via is disposed between two coolant channels.

20. The stacked semiconductor device of claim 17, wherein:
the second semiconductor device further comprises a semiconductor material, a plurality of coolant channels facing away from the first semiconductor device, and at least one via; and
the at least one via is disposed between two coolant channels.

21-45. (canceled)
